(19) United States
(12) Patent Application Publication
(10) Pub. No.: US 2026/0236834 A1
(43) Pub. Date: Aug. 13, 2026

(54) METHODS, ARCHITECTURES, APPARATUSES AND SYSTEMS FOR ONLINE TRAINING AND SELECTION OF NEURAL BELIEF PROPAGATION DECODERS

(71) Applicant: InterDigital Patent Holdings, Inc., Wilmington, DE (US)

(72) Inventors: Anouar Yatribi, London (GB); Ahmet Serdar Tan, London (GB); Arman Shojaeifard, London (GB)

(21) Appl. No.: 19/156,519

(22) PCT Filed: Feb. 26, 2024
(86) PCT No.: PCT/US2024/017245

§ 371 Date: Aug. 14, 2025

Related U.S. Application Data
(60) Provisional application No. 63/448,458, filed on Feb. 27, 2023.

(51) Int. Cl. G06N 20/00

(52) U.S. Cl. CPC G06N 20/00

(57) ABSTRACT

Procedures, methods, architectures, apparatuses, systems, devices, and computer program products for online training and/or selection of neural belief propagation (NBP) decoders are provided. A method may include receiving training configuration information indicating: an index of a neural belief propagation (NBP) variant or architecture and/or an update to one or more received hyperparameters for the NBP variant or architecture. The method may include sending an indication that the WTRU is ready to train the NBP variant or architecture, receiving a training dataset comprising all-zero codewords associated with a channel coding technique, starting training of the NBP variant or architecture using the received training dataset and/or the hyperparameters and, after one or more training iterations, sending information indicating a cost function value associated with the trained NBP variant or architecture. When the training is completed, the method may include sending information indicating trained weights associated with the trained NBP variant or architecture.

### CROSS-REFERENCE TO RELATED APPLICATIONS

This application claims the benefit of U.S. Provisional Patent Application No. 63/448,458, filed Feb. 27, 2023, which is incorporated herein by reference in its entirety.

### FIELD

Various embodiments described in the present disclosure are generally directed to the fields of communications, software and encoding, including, for example, to methods, architectures, apparatuses, systems related to online training and/or selection of neural belief propagation (NBP) decoders.

### BACKGROUND

Neural Belief Propagation (NBP) decoding is a decoding scheme that can enable the decoding of different families of error correcting codes. NBP decoding may be considered a result of the hybridization of deep neural networks (DNNs) and belief propagation (BP) decoding.

### SUMMARY

An embodiment may be directed to a method implemented in a Wireless Transmit/Receive Unit (WTRU). The method may include receiving, from a network element, training configuration information indicating (i) an index of a neural belief propagation (NBP) variant or architecture and/or (ii) an update to one or more received hyperparameters for the NBP variant or architecture. The method may include sending, to the network element, first information indicating that the WTRU is ready to train the NBP variant or architecture, and receiving, from the network element, a training dataset comprising all-zero codewords associated with a channel coding technique. The all-zero codewords may have a defined information block length and code rate. The method may then include starting training of the NBP variant or architecture using any of the received training dataset and the hyperparameters. After one or more training iterations, the method may include sending, to the network element, second information indicating a cost function value associated with the trained NBP variant or architecture and, on condition that the training is completed, sending, to the network element, third information indicating trained weights associated with the trained NBP variant or architecture.

An embodiment may be directed to a WTRU including circuitry (e.g., a processor, memory, and/or transceiver) configured to receive, from a network element, training configuration information indicating (i) an index of a neural belief propagation (NBP) variant or architecture and/or (ii) an update to one or more received hyperparameters for the NBP variant or architecture. The WTRU may be configured to send, to the network element, first information indicating that the WTRU is ready to train the NBP variant or architecture, and receive, from the network element, a training dataset comprising all-zero codewords associated with a channel coding technique. The all-zero codewords may have a defined information block length and code rate. The WTRU may be configured to begin training of the NBP variant or architecture using any of the received training dataset and the hyperparameters. After one or more training iterations, the WTRU may be configured to send, to the network element, second information indicating a cost function value associated with the trained NBP variant or architecture and, on condition that the training is completed, to send third information indicating trained weights associated with the trained NBP variant or architecture.

In various embodiments, the method may include, or the WTRU may be configured for, receiving configuration information indicating a lookup table associating NBP models and parameters.

In various embodiments, the NBP models may include a FNSPA, RNSPA, FNNMS, RNNMS, NBP-SS, and/or NBP-SS-PAN.

In various embodiments, the method may include, or the WTRU may be configured for, receiving a training indicator from the network element, where the training indicator comprises any of: an indication about the number of OFDM symbol, slots and subframes after which the training is supposed to start.

In various embodiments, the method may include, or the WTRU may be configured for, transmitting, to the network element, a request to receive the training configuration. In some embodiments, the second information may be sent after every training iteration, after a pre-defined set of iterations, and/or when the training is completed.

In various embodiments, the training is completed (e.g., considered to be completed) after completing all the training iterations or on a condition that a loss function of the NBP variant or architecture exceeds a pre-defined threshold.

In various embodiments, the method may include, or the WTRU may be configured for, receiving a BLER Reference Signal (BRS) from the network element, where the BRS may indicate pairs of SNR/BLER values and/or the index of the NBP. In an embodiment, the method may include (or the WTRU configured to) comparing the SNR/BLER values with those in a stored BLER table, determining whether weights of the NBP model should be updated based on the comparison and, on a condition that the weights are updated, transmitting an indication of the update to the model to the network element.

In various embodiments, the training may be performed collaboratively with, or among, at least one other WTRU (e.g., multiple WTRUs), and the third information may indicate calculated gradients and an index associated with a training iteration.

In various embodiments, the method may include, or the WTRU may be configured for, receiving or sending an evaluation request indicator indicating any of the NBP model index and Monte-Carlo parameters associated with the NBP model, receiving or sending an evaluation ready indicator (ERI), sending a set of codewords and their index, and receiving an evaluation complete indicator when a stopping criteria are met.

In various embodiments, the method may include, or the WTRU may be configured for, sending, to the network element, a request to train a parameter adapter network (PAN) and receiving, from the network element, a PAN configuration signal indicating any of: the PAN architecture and parameters, and/or a CSI-RS for estimating the channel.

In various embodiments, the request to train the PAN may be sent together with the request to receive the training configuration.

In various embodiments, the method may include, or the WTRU may be configured for, selecting the NBP variant or architecture using a selection criteria based on any one or more of: latency, complexity, reliability, channel condition, and code parameters.

### BRIEF DESCRIPTION OF THE DRAWINGS

A more detailed understanding may be had from the detailed description below, given by way of example in conjunction with drawings appended hereto. Figures in such drawings, like the detailed description, are examples. As such, the Figures (FIGs.) and the detailed description are not to be considered limiting, and other equally effective examples are possible and likely. Furthermore, like reference numerals (“ref.”) in the FIGs. indicate like elements, and wherein:

FIG. 1A is a system diagram illustrating an example communications system;

FIG. 1B is a system diagram illustrating an example wireless transmit/receive unit (WTRU) that may be used within the communications system illustrated in FIG. 1A;

FIG. 1C is a system diagram illustrating an example radio access network (RAN) and an example core network (CN) that may be used within the communications system illustrated in FIG. 1A;

FIG. 1D is a system diagram illustrating a further example RAN and a further example CN that may be used within the communications system illustrated in FIG. 1A;

FIG. 2 illustrates an example FNSPA decoding architecture

FIG. 3 illustrates an example of two unfolds of a relaxed RNN based NBP architecture;

FIG. 4 illustrates an example signal flow diagram, according to an example embodiment;

FIG. 5 illustrates an example flow diagram of a method for NBP training, according to an example embodiment; and

FIG. 6 illustrates an example a PAN architecture, according to various embodiments.

### DETAILED DESCRIPTION

In the following detailed description, numerous specific details are set forth to provide a thorough understanding of embodiments and/or examples disclosed herein. However, it will be understood that such embodiments and examples may be practiced without some or all of the specific details set forth herein. In other instances, well-known methods, procedures, components and circuits have not been described in detail, so as not to obscure the following description. Further, embodiments and examples not specifically described herein may be practiced in lieu of, or in combination with, the embodiments and other examples described, disclosed or otherwise provided explicitly, implicitly and/or inherently (collectively “provided”) herein. Although various embodiments are described and/or claimed herein in which an apparatus, system, device, etc. and/or any element thereof carries out an operation, process, algorithm, function, etc. and/or any portion thereof, it is to be understood that any embodiments described and/or claimed herein assume that any apparatus, system, device, etc. and/or any element thereof is configured to carry out any operation, process, algorithm, function, etc. and/or any portion thereof.

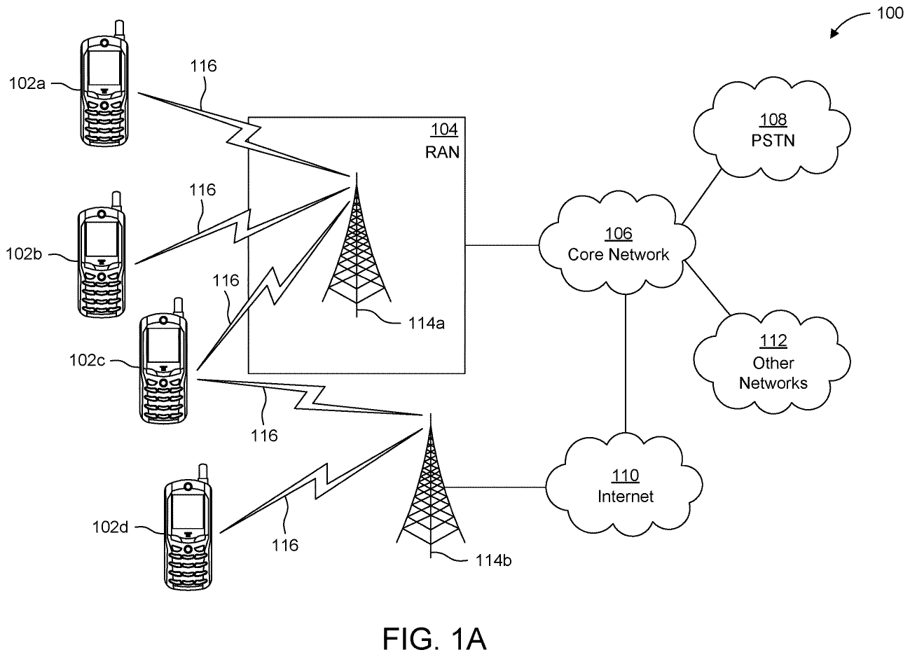

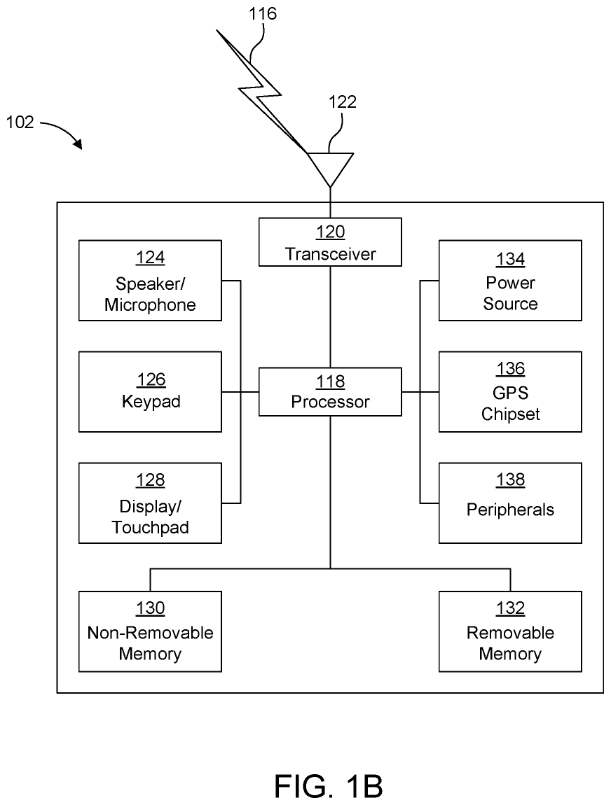

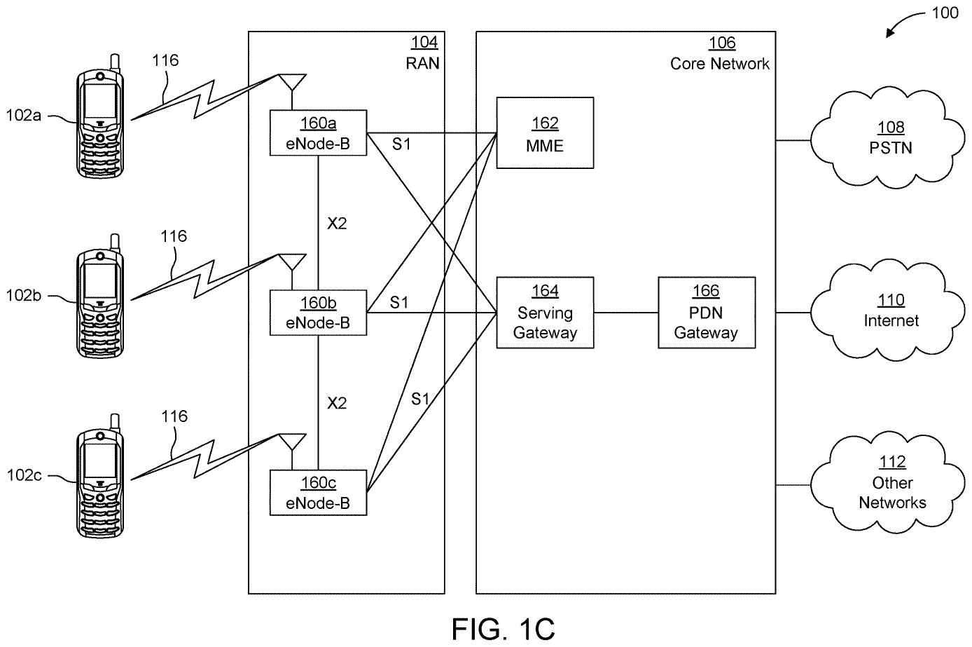

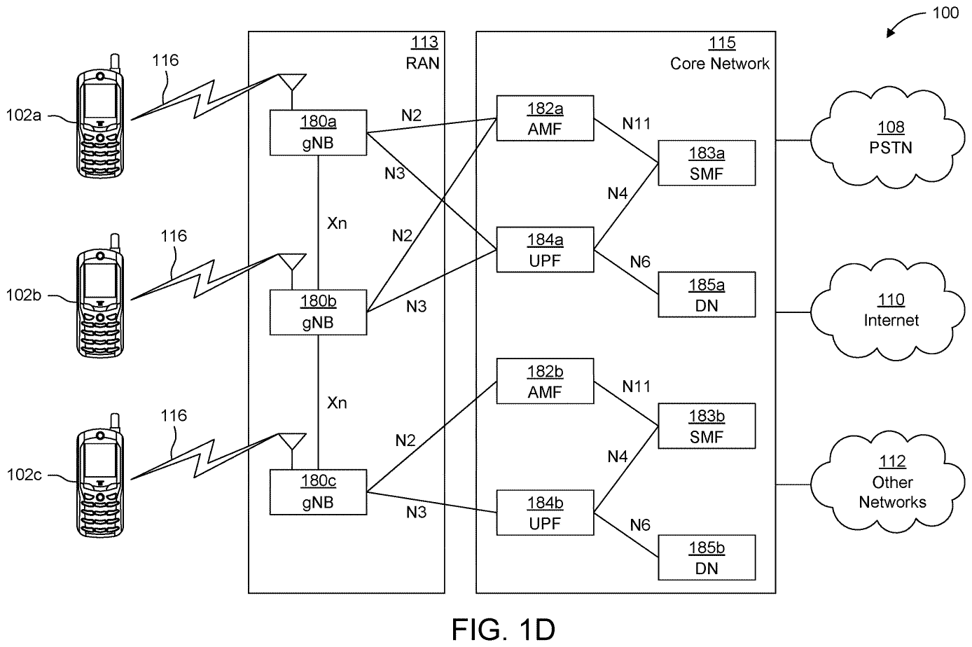

The methods, apparatuses and systems provided herein are well-suited for communications involving both wired and wireless networks. An overview of various types of wireless devices and infrastructure is provided with respect to FIGS. 1A-1D, where various elements of the network may utilize, perform, be arranged in accordance with and/or be adapted and/or configured for the methods, apparatuses and systems provided herein.

FIG. 1A is a system diagram illustrating an example communications system 100 in which one or more disclosed embodiments may be implemented. The communications system 100 may be a multiple access system that provides content, such as voice, data, video, messaging, broadcast, etc., to multiple wireless users. The communications system 100 may enable multiple wireless users to access such content through the sharing of system resources, including wireless bandwidth. For example, the communications systems 100 may employ one or more channel access methods, such as code division multiple access (CDMA), time division multiple access (TDMA), frequency division multiple access (FDMA), orthogonal FDMA (OFDMA), single-carrier FDMA (SC-FDMA), zero-tail (ZT) unique-word (UW) discreet Fourier transform (DFT) spread OFDM (ZT UW DTS-s OFDM), unique word OFDM (UW-OFDM), resource block-filtered OFDM, filter bank multicarrier (FBMC), and the like.

As shown in FIG. 1A, the communications system 100 may include wireless transmit/receive units (WTRUs) 102a, 102b, 102c, 102d, a radio access network (RAN) 104/113, a core network (CN) 106/115, a public switched telephone network (PSTN) 108, the Internet 110, and other networks 112, though it will be appreciated that the disclosed embodiments contemplate any number of WTRUs, base stations, networks, and/or network elements. Each of the WTRUs 102a, 102b, 102c, 102d may be any type of device configured to operate and/or communicate in a wireless environment. By way of example, the WTRUs 102a, 102b, 102c, 102d, any of which may be referred to as a “station” and/or a “STA”, may be configured to transmit and/or receive wireless signals and may include (or be) a user equipment (UE), a mobile station, a fixed or mobile subscriber unit, a subscription-based unit, a pager, a cellular telephone, a personal digital assistant (PDA), a smartphone, a laptop, a netbook, a personal computer, a wireless sensor, a hotspot or Mi-Fi device, an Internet of Things (IoT) device, a watch or other wearable, a head-mounted display (HMD), a vehicle, a drone, a medical device and applications (e.g., remote surgery), an industrial device and applications (e.g., a robot and/or other wireless devices operating in an industrial and/or an automated processing chain contexts), a consumer electronics device, a device operating on commercial and/or industrial wireless networks, and the like. Any of the WTRUs 102a, 102b, 102c and 102d, or any other WTRU mentioned or described herein, may be interchangeably referred to as a UE.

The communications systems 100 may also include a base station 114a and/or a base station 114b. Each of the base stations 114a, 114b may be any type of device configured to wirelessly interface with at least one of the WTRUs 102a, 102b, 102c, 102d, e.g., to facilitate access to one or more communication networks, such as the CN 106/115, the Internet 110, and/or the networks 112. By way of example, the base stations 114a, 114b may be any of a base transceiver station (BTS), a Node-B (NB), an eNode-B (eNB), a Home Node-B (HNB), a Home eNode-B (HeNB), a gNode-B (gNB), a NR Node-B (NR NB), a site controller, an access point (AP), a wireless router, and the like. While the base stations 114a, 114b are each depicted as a single element, it will be appreciated that the base stations 114a, 114b may include any number of interconnected base stations and/or network elements.

The base station 114a may be part of the RAN 104/113, which may also include other base stations and/or network elements (not shown), such as a base station controller (BSC), a radio network controller (RNC), relay nodes, etc. The base station 114a and/or the base station 114b may be configured to transmit and/or receive wireless signals on one or more carrier frequencies, which may be referred to as a cell (not shown). These frequencies may be in licensed spectrum, unlicensed spectrum, or a combination of licensed and unlicensed spectrum. A cell may provide coverage for a wireless service to a specific geographical area that may be relatively fixed or that may change over time. The cell may further be divided into cell sectors. For example, the cell associated with the base station 114a may be divided into three sectors. Thus, in an embodiment, the base station 114a may include three transceivers, i.e., one for each sector of the cell. In an embodiment, the base station 114a may employ multiple-input multiple output (MIMO) technology and may utilize multiple transceivers for each or any sector of the cell. For example, beamforming may be used to transmit and/or receive signals in desired spatial directions.

The base stations 114a, 114b may communicate with one or more of the WTRUs 102a, 102b, 102c, 102d over an air interface 116, which may be any suitable wireless communication link (e.g., radio frequency (RF), microwave, centimeter wave, micrometer wave, infrared (IR), ultraviolet (UV), visible light, etc.). The air interface 116 may be established using any suitable radio access technology (RAT).

More specifically, as noted above, the communications system 100 may be a multiple access system and may employ one or more channel access schemes, such as CDMA, TDMA, FDMA, OFDMA, SC-FDMA, and the like. For example, the base station 114a in the RAN 104/113 and the WTRUs 102a, 102b, 102c may implement a radio technology such as Universal Mobile Telecommunications System (UMTS) Terrestrial Radio Access (UTRA), which may establish the air interface 116 using wideband CDMA (WCDMA). WCDMA may include communication protocols such as High-Speed Packet Access (HSPA) and/or Evolved HSPA (HSPA+). HSPA may include High-Speed Downlink Packet Access (HSDPA) and/or High-Speed Uplink Packet Access (HSUPA).

In an embodiment, the base station 114a and the WTRUs 102a, 102b, 102c may implement a radio technology such as Evolved UMTS Terrestrial Radio Access (E-UTRA), which may establish the air interface 116 using Long Term Evolution (LTE) and/or LTE-Advanced (LTE-A) and/or LTE-Advanced Pro (LTE-A Pro).

In an embodiment, the base station 114a and the WTRUs 102a, 102b, 102c may implement a radio technology such as NR Radio Access, which may establish the air interface 116 using New Radio (NR).

In an embodiment, the base station 114a and the WTRUs 102a, 102b, 102c may implement multiple radio access technologies. For example, the base station 114a and the WTRUs 102a, 102b, 102c may implement LTE radio access and NR radio access together, for instance using dual connectivity (DC) principles. Thus, the air interface utilized by WTRUs 102a, 102b, 102c may be characterized by multiple types of radio access technologies and/or transmissions sent to/from multiple types of base stations (e.g., an eNB and a gNB).

In an embodiment, the base station 114a and the WTRUs 102a, 102b, 102c may implement radio technologies such as IEEE 802.11 (i.e., Wireless Fidelity (Wi-Fi), IEEE 802.16 (i.e., Worldwide Interoperability for Microwave Access (WiMAX)), CDMA2000, CDMA2000 1×, CDMA2000 EV-DO, Interim Standard 2000 (IS-2000), Interim Standard 95 (IS-95), Interim Standard 856 (IS-856), Global System for Mobile communications (GSM), Enhanced Data rates for GSM Evolution (EDGE), GSM EDGE (GERAN), and the like.

The base station 114b in FIG. 1A may be a wireless router, Home Node-B, Home eNode-B, or access point, for example, and may utilize any suitable RAT for facilitating wireless connectivity in a localized area, such as a place of business, a home, a vehicle, a campus, an industrial facility, an air corridor (e.g., for use by drones), a roadway, and the like. In an embodiment, the base station 114b and the WTRUs 102c, 102d may implement a radio technology such as IEEE 802.11 to establish a wireless local area network (WLAN). In an embodiment, the base station 114b and the WTRUs 102c, 102d may implement a radio technology such as IEEE 802.15 to establish a wireless personal area network (WPAN). In an embodiment, the base station 114b and the WTRUs 102c, 102d may utilize a cellular-based RAT (e.g., WCDMA, CDMA2000, GSM, LTE, LTE-A, LTE-A Pro, NR, etc.) to establish any of a small cell, picocell or femtocell. As shown in FIG. 1A, the base station 114b may have a direct connection to the Internet 110. Thus, the base station 114b may not be required to access the Internet 110 via the CN 106/115.

The RAN 104/113 may be in communication with the CN 106/115, which may be any type of network configured to provide voice, data, applications, and/or voice over internet protocol (VoIP) services to one or more of the WTRUs 102a, 102b, 102c, 102d. The data may have varying quality of service (QoS) requirements, such as differing throughput requirements, latency requirements, error tolerance requirements, reliability requirements, data throughput requirements, mobility requirements, and the like. The CN 106/115 may provide call control, billing services, mobile location-based services, pre-paid calling, Internet connectivity, video distribution, etc., and/or perform high-level security functions, such as user authentication. Although not shown in FIG. 1A, it will be appreciated that the RAN 104/113 and/or the CN 106/115 may be in direct or indirect communication with other RANs that employ the same RAT as the RAN 104/113 or a different RAT. For example, in addition to being connected to the RAN 104/113, which may be utilizing an NR radio technology, the CN 106/115 may also be in communication with another RAN (not shown) employing any of a GSM, UMTS, CDMA 2000, WiMAX, E-UTRA, or Wi-Fi radio technology.

The CN 106/115 may also serve as a gateway for the WTRUs 102a, 102b, 102c, 102d to access the PSTN 108, the Internet 110, and/or other networks 112. The PSTN 108 may include circuit-switched telephone networks that provide plain old telephone service (POTS). The Internet 110 may include a global system of interconnected computer networks and devices that use common communication protocols, such as the transmission control protocol (TCP), user datagram protocol (UDP) and/or the internet protocol (IP) in the TCP/IP internet protocol suite. The networks 112 may include wired and/or wireless communications networks owned and/or operated by other service providers. For example, the networks 112 may include another CN connected to one or more RANs, which may employ the same RAT as the RAN 104/114 or a different RAT.

Some or all of the WTRUs 102a, 102b, 102c, 102d in the communications system 100 may include multi-mode capabilities (e.g., the WTRUs 102a, 102b, 102c, 102d may include multiple transceivers for communicating with different wireless networks over different wireless links). For example, the WTRU 102c shown in FIG. 1A may be configured to communicate with the base station 114a, which may employ a cellular-based radio technology, and with the base station 114b, which may employ an IEEE 802 radio technology.

FIG. 1B is a system diagram illustrating an example WTRU 102. As shown in FIG. 1, the WTRU 102 may include a processor 118, a transceiver 120, a transmit/receive element 122, a speaker/microphone 124, a keypad 126, a display/touchpad 128, non-removable memory 130, removable memory 132, a power source 134, a global positioning system (GPS) chipset 136, and/or other elements/peripherals 138, among others. It will be appreciated that the WTRU 102 may include any sub-combination of the foregoing elements while remaining consistent with an embodiment.

The processor 118 may be a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), a state machine, and the like. The processor 118 may perform signal coding, data processing, power control, input/output processing, and/or any other functionality that enables the WTRU 102 to operate in a wireless environment. The processor 118 may be coupled to the transceiver 120, which may be coupled to the transmit/receive element 122. While FIG. 1B depicts the processor 118 and the transceiver 120 as separate components, it will be appreciated that the processor 118 and the transceiver 120 may be integrated together, e.g., in an electronic package or chip.

The transmit/receive element 122 may be configured to transmit signals to, or receive signals from, a base station (e.g., the base station 114a) over the air interface 116. For example, in an embodiment, the transmit/receive element 122 may be an antenna configured to transmit and/or receive RF signals. In an embodiment, the transmit/receive element 122 may be an emitter/detector configured to transmit and/or receive IR, UV, or visible light signals, for example. In an embodiment, the transmit/receive element 122 may be configured to transmit and/or receive both RF and light signals. It will be appreciated that the transmit/receive element 122 may be configured to transmit and/or receive any combination of wireless signals.

Although the transmit/receive element 122 is depicted in FIG. 1B as a single element, the WTRU 102 may include any number of transmit/receive elements 122. For example, the WTRU 102 may employ MIMO technology. Thus, in an embodiment, the WTRU 102 may include two or more transmit/receive elements 122 (e.g., multiple antennas) for transmitting and receiving wireless signals over the air interface 116.

The transceiver 120 may be configured to modulate the signals that are to be transmitted by the transmit/receive element 122 and to demodulate the signals that are received by the transmit/receive element 122. As noted above, the WTRU 102 may have multi-mode capabilities. Thus, the transceiver 120 may include multiple transceivers for enabling the WTRU 102 to communicate via multiple RATs, such as NR and IEEE 802.11, for example.

The processor 118 of the WTRU 102 may be coupled to, and may receive user input data from, the speaker/microphone 124, the keypad 126, and/or the display/touchpad 128 (e.g., a liquid crystal display (LCD) display unit or organic light-emitting diode (OLED) display unit). The processor 118 may also output user data to the speaker/microphone 124, the keypad 126, and/or the display/touchpad 128. In addition, the processor 118 may access information from, and store data in, any type of suitable memory, such as the non-removable memory 130 and/or the removable memory 132. The non-removable memory 130 may include random-access memory (RAM), read-only memory (ROM), a hard disk, or any other type of memory storage device. The removable memory 132 may include a subscriber identity module (SIM) card, a memory stick, a secure digital (SD) memory card, and the like. In other embodiments, the processor 118 may access information from, and store data in, memory that is not physically located on the WTRU 102, such as on a server or a home computer (not shown).

The processor 118 may receive power from the power source 134, and may be configured to distribute and/or control the power to the other components in the WTRU 102. The power source 134 may be any suitable device for powering the WTRU 102. For example, the power source 134 may include one or more dry cell batteries (e.g., nickel-cadmium (NiCd), nickel-zinc (NiZn), nickel metal hydride (NiMH), lithium-ion (Li-ion), etc.), solar cells, fuel cells, and the like.

The processor 118 may also be coupled to the GPS chipset 136, which may be configured to provide location information (e.g., longitude and latitude) regarding the current location of the WTRU 102. In addition to, or in lieu of, the information from the GPS chipset 136, the WTRU 102 may receive location information over the air interface 116 from a base station (e.g., base stations 114a, 114b) and/or determine its location based on the timing of the signals being received from two or more nearby base stations. It will be appreciated that the WTRU 102 may acquire location information by way of any suitable location-determination method while remaining consistent with an embodiment.

The processor 118 may further be coupled to other elements/peripherals 138, which may include one or more software and/or hardware modules/units that provide additional features, functionality and/or wired or wireless connectivity. For example, the elements/peripherals 138 may include an accelerometer, an e-compass, a satellite transceiver, a digital camera (e.g., for photographs and/or video), a universal serial bus (USB) port, a vibration device, a television transceiver, a hands free headset, a Bluetooth® module, a frequency modulated (FM) radio unit, a digital music player, a media player, a video game player module, an Internet browser, a virtual reality and/or augmented reality (VR/AR) device, an activity tracker, and the like. The elements/peripherals 138 may include one or more sensors, the sensors may be one or more of a gyroscope, an accelerometer, a hall effect sensor, a magnetometer, an orientation sensor, a proximity sensor, a temperature sensor, a time sensor; a geolocation sensor; an altimeter, a light sensor, a touch sensor, a magnetometer, a barometer, a gesture sensor, a biometric sensor, and/or a humidity sensor.

The WTRU 102 may include a full duplex radio for which transmission and reception of some or all of the signals (e.g., associated with particular subframes for both the uplink (e.g., for transmission) and downlink (e.g., for reception) may be concurrent and/or simultaneous. The full duplex radio may include an interference management unit to reduce and or substantially eliminate self-interference via either hardware (e.g., a choke) or signal processing via a processor (e.g., a separate processor (not shown) or via processor 118). In an embodiment, the WTRU 102 may include a half-duplex radio for which transmission and reception of some or all of the signals (e.g., associated with particular subframes for either the uplink (e.g., for transmission) or the downlink (e.g., for reception)).

FIG. 1C is a system diagram illustrating the RAN 104 and the CN 106 according to an embodiment. As noted above, the RAN 104 may employ an E-UTRA radio technology to communicate with the WTRUs 102a, 102b, and 102c over the air interface 116. The RAN 104 may also be in communication with the CN 106.

The RAN 104 may include eNode-Bs 160a, 160b, 160c, though it will be appreciated that the RAN 104 may include any number of eNode-Bs while remaining consistent with an embodiment. The eNode-Bs 160a, 160b, 160c may each include one or more transceivers for communicating with the WTRUs 102a, 102b, 102c over the air interface 116. In an embodiment, the eNode-Bs 160a, 160b, 160c may implement MIMO technology. Thus, the eNode-B 160a, for example, may use multiple antennas to transmit wireless signals to, and receive wireless signals from, the WTRU 102a.

Each of the eNode-Bs 160a, 160b, and 160c may be associated with a particular cell (not shown) and may be configured to handle radio resource management decisions, handover decisions, scheduling of users in the uplink (UL) and/or downlink (DL), and the like. As shown in FIG. 1C, the eNode-Bs 160a, 160b, 160c may communicate with one another over an X2 interface.

The CN 106 shown in FIG. 1C may include a mobility management entity (MME) 162, a serving gateway (SGW) 164, and a packet data network (PDN) gateway (PGW) 166. While each of the foregoing elements are depicted as part of the CN 106, it will be appreciated that any one of these elements may be owned and/or operated by an entity other than the CN operator.

The MME 162 may be connected to each of the eNode-Bs 160a, 160b, and 160c in the RAN 104 via an S1 interface and may serve as a control node. For example, the MME 162 may be responsible for authenticating users of the WTRUs 102a, 102b, 102c, bearer activation/deactivation, selecting a particular serving gateway during an initial attach of the WTRUs 102a, 102b, 102c, and the like. The MME 162 may provide a control plane function for switching between the RAN 104 and other RANs (not shown) that employ other radio technologies, such as GSM and/or WCDMA.

The SGW 164 may be connected to each of the eNode-Bs 160a, 160b, 160c in the RAN 104 via the S1 interface. The SGW 164 may generally route and forward user data packets to/from the WTRUs 102a, 102b, 102c. The SGW 164 may perform other functions, such as anchoring user planes during inter-eNode-B handovers, triggering paging when DL data is available for the WTRUs 102a, 102b, 102c, managing and storing contexts of the WTRUs 102a, 102b, 102c, and the like.

The SGW 164 may be connected to the PGW 166, which may provide the WTRUs 102a, 102b, 102c with access to packet-switched networks, such as the Internet 110, to facilitate communications between the WTRUs 102a, 102b, 102c and IP-enabled devices.

The CN 106 may facilitate communications with other networks. For example, the CN 106 may provide the WTRUs 102a, 102b, 102c with access to circuit-switched networks, such as the PSTN 108, to facilitate communications between the WTRUs 102a, 102b, 102c and traditional land-line communications devices. For example, the CN 106 may include, or may communicate with, an IP gateway (e.g., an IP multimedia subsystem (IMS) server) that serves as an interface between the CN 106 and the PSTN 108. In addition, the CN 106 may provide the WTRUs 102a, 102b, 102c with access to the other networks 112, which may include other wired and/or wireless networks that are owned and/or operated by other service providers.

Although the WTRU is described in FIGS. 1A-1D as a wireless terminal, it is contemplated that in certain representative embodiments that such a terminal may use (e.g., temporarily or permanently) wired communication interfaces with the communication network.

In representative embodiments, the other network 112 may be a WLAN.

A WLAN in infrastructure basic service set (BSS) mode may have an access point (AP) for the BSS and one or more stations (STAs) associated with the AP. The AP may have an access or an interface to a distribution system (DS) or another type of wired/wireless network that carries traffic into and/or out of the BSS. Traffic to STAs that originates from outside the BSS may arrive through the AP and may be delivered to the STAs. Traffic originating from STAs to destinations outside the BSS may be sent to the AP to be delivered to respective destinations. Traffic between STAs within the BSS may be sent through the AP, for example, where the source STA may send traffic to the AP and the AP may deliver the traffic to the destination STA. The traffic between STAs within a BSS may be considered and/or referred to as peer-to-peer traffic. The peer-to-peer traffic may be sent between (e.g., directly between) the source and destination STAs with a direct link setup (DLS). In certain representative embodiments, the DLS may use an 802.11e DLS or an 802.11z tunneled DLS (TDLS). A WLAN using an Independent BSS (IBSS) mode may not have an AP, and the STAs (e.g., all of the STAs) within or using the IBSS may communicate directly with each other. The IBSS mode of communication may sometimes be referred to herein as an “ad-hoc” mode of communication.

When using the 802.1 lac infrastructure mode of operation or a similar mode of operations, the AP may transmit a beacon on a fixed channel, such as a primary channel. The primary channel may be a fixed width (e.g., 20 MHz wide bandwidth) or a dynamically set width via signaling. The primary channel may be the operating channel of the BSS and may be used by the STAs to establish a connection with the AP. In certain representative embodiments, Carrier sense multiple access with collision avoidance (CSMA/CA) may be implemented, for example in in 802.11 systems. For CSMA/CA, the STAs (e.g., every STA), including the AP, may sense the primary channel. If the primary channel is sensed/detected and/or determined to be busy by a particular STA, the particular STA may back off. One STA (e.g., only one station) may transmit at any given time in a given BSS.

High throughput (HT) STAs may use a 40 MHz wide channel for communication, for example, via a combination of the primary 20 MHz channel with an adjacent or nonadjacent 20 MHz channel to form a 40 MHz wide channel.

Very high throughput (VHT) STAs may support 20 MHz, 40 MHz, 80 MHz, and/or 160 MHz wide channels. The 40 MHz, and/or 80 MHz, channels may be formed by combining contiguous 20 MHz channels. A 160 MHz channel may be formed by combining 8 contiguous 20 MHz channels, or by combining two non-contiguous 80 MHz channels, which may be referred to as an 80+80 configuration. For the 80+80 configuration, the data, after channel encoding, may be passed through a segment parser that may divide the data into two streams. Inverse fast fourier transform (IFFT) processing, and time domain processing, may be done on each stream separately. The streams may be mapped on to the two 80 MHz channels, and the data may be transmitted by a transmitting STA. At the receiver of the receiving STA, the above-described operation for the 80+80 configuration may be reversed, and the combined data may be sent to a medium access control (MAC) layer, entity, etc.

Sub 1 GHz modes of operation are supported by 802.11af and 802.11ah. The channel operating bandwidths, and carriers, are reduced in 802.11af and 802.11ah relative to those used in 802.11n, and 802.11ac. 802.11af supports 5 MHz, 10 MHz and 20 MHz bandwidths in the TV white space (TVWS) spectrum, and 802.11ah supports 1 MHz, 2 MHz, 4 MHz, 8 MHz, and 16 MHz bandwidths using non-TVWS spectrum. According to a representative embodiment, 802.11ah may support meter type control/machine-type communications (MTC), such as MTC devices in a macro coverage area. MTC devices may have certain capabilities, for example, limited capabilities including support for (e.g., only support for) certain and/or limited bandwidths. The MTC devices may include a battery with a battery life above a threshold (e.g., to maintain a very long battery life).

WLAN systems, which may support multiple channels, and channel bandwidths, such as 802.11n, 802.11ac, 802.11af, and 802.11ah, include a channel which may be designated as the primary channel. The primary channel may have a bandwidth equal to the largest common operating bandwidth supported by all STAs in the BSS. The bandwidth of the primary channel may be set and/or limited by a STA, from among all STAs in operating in a BSS, which supports the smallest bandwidth operating mode. In the example of 802.11ah, the primary channel may be 1 MHz wide for STAs (e.g., MTC type devices) that support (e.g., only support) a 1 MHz mode, even if the AP, and other STAs in the BSS support 2 MHz, 4 MHz, 8 MHz, 16 MHz, and/or other channel bandwidth operating modes. Carrier sensing and/or network allocation vector (NAV) settings may depend on the status of the primary channel. If the primary channel is busy, for example, due to a STA (which supports only a 1 MHz operating mode), transmitting to the AP, the entire available frequency bands may be considered busy even though a majority of the frequency bands remains idle and may be available.

In the United States, the available frequency bands, which may be used by 802.11ah, are from 902 MHz to 928 MHz. In Korea, the available frequency bands are from 917.5 MHz to 923.5 MHz. In Japan, the available frequency bands are from 916.5 MHz to 927.5 MHz. The total bandwidth available for 802.11ah is 6 MHz to 26 MHz depending on the country code.

FIG. 1D is a system diagram illustrating the RAN 113 and the CN 115 according to an embodiment. As noted above, the RAN 113 may employ an NR radio technology to communicate with the WTRUs 102a, 102b, 102c over the air interface 116. The RAN 113 may also be in communication with the CN 115.

The RAN 113 may include gNBs 180a, 180b, 180c, though it will be appreciated that the RAN 113 may include any number of gNBs while remaining consistent with an embodiment. The gNBs 180a, 180b, 180c may each include one or more transceivers for communicating with the WTRUs 102a, 102b, 102c over the air interface 116. In an embodiment, the gNBs 180a, 180b, 180c may implement MIMO technology. For example, gNBs 180a, 180b may utilize beamforming to transmit signals to and/or receive signals from the WTRUs 102a, 102b, 102c. Thus, the gNB 180a, for example, may use multiple antennas to transmit wireless signals to, and/or receive wireless signals from, the WTRU 102a. In an embodiment, the gNBs 180a, 180b, 180c may implement carrier aggregation technology. For example, the gNB 180a may transmit multiple component carriers to the WTRU 102a (not shown). A subset of these component carriers may be on unlicensed spectrum while the remaining component carriers may be on licensed spectrum. In an embodiment, the gNBs 180a, 180b, 180c may implement Coordinated Multi-Point (CoMP) technology. For example, WTRU 102a may receive coordinated transmissions from gNB 180a and gNB 180b (and/or gNB 180c).

The WTRUs 102a, 102b, 102c may communicate with gNBs 180a, 180b, 180c using transmissions associated with a scalable numerology. For example, OFDM symbol spacing and/or OFDM subcarrier spacing may vary for different transmissions, different cells, and/or different portions of the wireless transmission spectrum. The WTRUs 102a, 102b, 102c may communicate with gNBs 180a, 180b, 180c using subframe or transmission time intervals (TTIs) of various or scalable lengths (e.g., including a varying number of OFDM symbols and/or lasting varying lengths of absolute time).

The gNBs 180a, 180b, 180c may be configured to communicate with the WTRUs 102a, 102b, 102c in a standalone configuration and/or a non-standalone configuration. In the standalone configuration, WTRUs 102a, 102b, 102c may communicate with gNBs 180a, 180b, 180c without also accessing other RANs (e.g., such as eNode-Bs 160a, 160b, 160c). In the standalone configuration, WTRUs 102a, 102b, 102c may utilize one or more of gNBs 180a, 180b, 180c as a mobility anchor point. In the standalone configuration, WTRUs 102a, 102b, 102c may communicate with gNBs 180a, 180b, 180c using signals in an unlicensed band. In a non-standalone configuration WTRUs 102a, 102b, 102c may communicate with/connect to gNBs 180a, 180b, 180c while also communicating with/connecting to another RAN such as eNode-Bs 160a, 160b, 160c. For example, WTRUs 102a, 102b, 102c may implement DC principles to communicate with one or more gNBs 180a, 180b, 180c and one or more eNode-Bs 160a, 160b, 160c substantially simultaneously. In the non-standalone configuration, eNode-Bs 160a, 160b, 160c may serve as a mobility anchor for WTRUs 102a, 102b, 102c and gNBs 180a, 180b, 180c may provide additional coverage and/or throughput for servicing WTRUs 102a, 102b, 102c.

Each of the gNBs 180a, 180b, 180c may be associated with a particular cell (not shown) and may be configured to handle radio resource management decisions, handover decisions, scheduling of users in the UL and/or DL, support of network slicing, dual connectivity, interworking between NR and E-UTRA, routing of user plane data towards user plane functions (UPFs) 184a, 184b, routing of control plane information towards access and mobility management functions (AMFs) 182a, 182b, and the like. As shown in FIG. 1D, the gNBs 180a, 180b, 180c may communicate with one another over an Xn interface.

The CN 115 shown in FIG. 1D may include at least one AMF 182a, 182b, at least one UPF 184a, 184b, at least one session management function (SMF) 183a, 183b, and at least one Data Network (DN) 185a, 185b. While each of the foregoing elements are depicted as part of the CN 115, it will be appreciated that any of these elements may be owned and/or operated by an entity other than the CN operator.

The AMF 182a, 182b may be connected to one or more of the gNBs 180a, 180b, 180c in the RAN 113 via an N2 interface and may serve as a control node. For example, the AMF 182a, 182b may be responsible for authenticating users of the WTRUs 102a, 102b, 102c, support for network slicing (e.g., handling of different protocol data unit (PDU) sessions with different requirements), selecting a particular SMF 183a, 183b, management of the registration area, termination of NAS signaling, mobility management, and the like. Network slicing may be used by the AMF 182a, 182b, e.g., to customize CN support for WTRUs 102a, 102b, 102c based on the types of services being utilized WTRUs 102a, 102b, 102c. For example, different network slices may be established for different use cases such as services relying on ultra-reliable low latency (URLLC) access, services relying on enhanced massive mobile broadband (eMBB) access, services for MTC access, and/or the like. The AMF 162 may provide a control plane function for switching between the RAN 113 and other RANs (not shown) that employ other radio technologies, such as LTE, LTE-A, LTE-A Pro, and/or non-3GPP access technologies such as Wi-Fi.

The SMF 183a, 183b may be connected to an AMF 182a, 182b in the CN 115 via an N11 interface. The SMF 183a, 183b may also be connected to a UPF 184a, 184b in the CN 115 via an N4 interface. The SMF 183a, 183b may select and control the UPF 184a, 184b and configure the routing of traffic through the UPF 184a, 184b. The SMF 183a, 183b may perform other functions, such as managing and allocating UE IP address, managing PDU sessions, controlling policy enforcement and QoS, providing downlink data notifications, and the like. A PDU session type may be IP-based, non-IP based, Ethernet-based, and the like.

The UPF 184a, 184b may be connected to one or more of the gNBs 180a, 180b, 180c in the RAN 113 via an N3 interface, which may provide the WTRUs 102a, 102b, 102c with access to packet-switched networks, such as the Internet 110, e.g., to facilitate communications between the WTRUs 102a, 102b, 102c and IP-enabled devices. The UPF 184, 184b may perform other functions, such as routing and forwarding packets, enforcing user plane policies, supporting multi-homed PDU sessions, handling user plane QoS, buffering downlink packets, providing mobility anchoring, and the like.

The CN 115 may facilitate communications with other networks. For example, the CN 115 may include, or may communicate with, an IP gateway (e.g., an IP multimedia subsystem (IMS) server) that serves as an interface between the CN 115 and the PSTN 108. In addition, the CN 115 may provide the WTRUs 102a, 102b, 102c with access to the other networks 112, which may include other wired and/or wireless networks that are owned and/or operated by other service providers. In an embodiment, the WTRUs 102a, 102b, 102c may be connected to a local Data Network (DN) 185a, 185b through the UPF 184a, 184b via the N3 interface to the UPF 184a, 184b and an N6 interface between the UPF 184a, 184b and the DN 185a, 185b.

In view of FIGS. 1A-1D, and the corresponding description of FIGS. 1A-1D, one or more, or all, of the functions described herein with regard to any of: WTRUs 102a-d, base stations 114a-b, eNode-Bs 160a-c, MME 162, SGW 164, PGW 166, gNBs 180a-c, AMFs 182a-b, UPFs 184a-b, SMFs 183a-b, DNs 185a-b, and/or any other element(s)/device(s) described herein, may be performed by one or more emulation elements/devices (not shown). The emulation devices may be one or more devices configured to emulate one or more, or all, of the functions described herein. For example, the emulation devices may be used to test other devices and/or to simulate network and/or WTRU functions.

The emulation devices may be designed to implement one or more tests of other devices in a lab environment and/or in an operator network environment. For example, the one or more emulation devices may perform the one or more, or all, functions while being fully or partially implemented and/or deployed as part of a wired and/or wireless communication network in order to test other devices within the communication network. The one or more emulation devices may perform the one or more, or all, functions while being temporarily implemented/deployed as part of a wired and/or wireless communication network. The emulation device may be directly coupled to another device for purposes of testing and/or may performing testing using over-the-air wireless communications.

The one or more emulation devices may perform the one or more, including all, functions while not being implemented/deployed as part of a wired and/or wireless communication network. For example, the emulation devices may be utilized in a testing scenario in a testing laboratory and/or a non-deployed (e.g., testing) wired and/or wireless communication network in order to implement testing of one or more components. The one or more emulation devices may be test equipment. Direct RF coupling and/or wireless communications via RF circuitry (e.g., which may include one or more antennas) may be used by the emulation devices to transmit and/or receive data.

Embodiments disclosed herein are representative and do not limit the applicability of the apparatus, procedures, functions and/or methods to any particular wireless technology, any particular communication technology and/or other technologies. The term network in this disclosure may generally refer to one or more base stations or gNBs or other network entity which in turn may be associated with one or more Transmission/Reception Points (TRPs), or to any other node in the radio access network.

It is noted that, throughout example embodiments described herein, the terms “serving base station”, “base station”, “gNB”, collectively “gNB” may be used interchangeably to designate any network element such as, e.g., a network element acting as a serving base station. Embodiments described herein are not limited to gNBs and are applicable to any other type of base stations.

Certain embodiments may generally relate to channel decoding variant selection and feedback, deep neural network (DNN) architecture selection and feedback, NBP decoder online training, NBP online evaluation, and/or signal-to-noise ratio (SNR) adaptive training. For example, some embodiments may provide methods to perform online training of Neural Belief Propagation (NBP) decoders, including methods and procedures for User-Centric selection of different variants and DNN architectures as well as the evaluation of the machine learning (ML) based decoding models, and SNR adaptive training, e.g., for a UE configured to support various NBP decoders and architectures for decoding different families of channel codes, such as low density parity check (LDPC), Polar, Reed-Muller and Bose-Chaudhuri-Hocquenghem (BCH) codes.

Neural Belief Propagation (NBP) decoding is a promising decoding scheme to adopt in future 3GPP releases and different use cases. The NBP enables to decode different families of error correcting codes, including LDPC, Polar, RM and BCH codes. Due to the use of DNNs to represent the graphical structure of the decoder that can be trained, the hardware implementation complexity is very reasonable and can be parallelizable. DNNs provide flexibility in terms of choosing various architectures and training paradigms, in addition to simplified variants of the BP-SP decoding algorithm.

These features may enable the UE to select from different architectures and variants, depending on its available resources and the channel conditions. This flexibility helps to optimize the decoding performance, as well as latency and complexity depending on the UE, while continuous learning of different variants and architectures can be considered as well.

If C(n, k) is a block code with a dimension (or information blocklength) k and codelength n, the code C is characterized by a parity-check matrix H, with M rows and n columns, where M≥n−k. The Tanner graph of this code, which is its graphical representation, is a bipartite graph with M check-nodes and n variable-nodes. Denoting by e=(c, v) the edge connecting the c^{th} CN to the v^{th} VN; Lₘₐₓ represents the maximum number of decoding iterations, and x_{i,e=(v,c)} represents the message passed between the c^{th} CN and the v^{th} VN at the i^{th} decoding iteration.

NBP decoding is the result of the hybridization of DNNs and belief propagation (BP) decoding. The core concept relies on unrolling the graphical representation (Tanner Graph) of a linear block code across all the decoding iterations and interpreting the resulting graph as a deep neural network, with edges connecting VNs to CNs. The DNN, which may be alternately referred to herein as NBP, can be appropriately trained using an optimizer, where the edges are trained iteratively to improve decoding performance (BER, BLER).

One of the main features of NBP decoders is that they provide a flexibility to choose between different architectures related to the DNN, while enabling different approaches for training and including other activation functions. Furthermore, NBP decoding allows to compensate the negative impact of short cycles, known to have a dramatic limitation on decoding performance of conventional message-passing decoding algorithms, especially for short codes where short cycles are inevitable.

NBP decoders can be applied to different families of Error Correcting Codes, including LDPC, Polar, RM and BCH codes. Also, if learned properly, the codes can be decoded with less decoding iterations compared to the plain BP decoders, while enhancing the performance and allowing parallelizable hardware implementations and processing.

In terms of complexity, NBP can be applied to different simplified variants of the original BP-SP algorithm, which offers a good solution for low-complexity and low-latency decoding, such as for the URLLC and mMTC use cases, while reducing error rates. For example, this can be very beneficial for high reliability and high-speed communications that require short information blocklengths.

The BP decoding algorithm can provide very good performance (especially for long blocklengths), while maintaining a low latency and low complexity. BP can decode any linear block code, however its main advantage is to operate on sparse parity-check matrices in order to provide low latency and low error propagation because of the small number of short cycles.

The BP decoding algorithm is an iterative message-passing algorithm, that operates on the Tanner Graph representation of the code. It is mainly composed of three dependent steps, excluding the initialization step, which are the Check-Node (CN) Update, Variable-Node (VN) Update, and Marginalization.

The CN update may include computing the reliability messages (LLRs) passed from CNs to VNs, by calculating the sum of extrinsic information provided from the VNs participating in each CN, excluding the contribution of the CN being considered itself. The CN update is known as the horizontal step, where the rows of the PCM are considered.

Similarly, the VN update may compute the extrinsic reliabilities of CNs where the considered VN participates and is known as the vertical step.

The marginalization step may represent the last operation of the iterative decoding process, and may output estimates of the LLRs of the bits being under decoding.

The BP decoder may have a stopping criterion, which can be the syndrome weight, i.e., when the hard decision of the received sample is a valid codeword then the syndrome weight is zero, which means that all the parity-check equations are satisfied. Another stopping criteria may be reaching the maximum number of decoding iterations Lₘₐₓ.

The main variant of the BP decoder is the BP-SPA, which guarantees robust performance for the entire SNR regime. However, a limitation of this variant is a slightly high complexity CN update step, which requires hyperbolic arithmetic operations. This limitation is in some use cases not desired, as some communication systems require a very low latency, and some UEs are energy-constrained and have low storage capacity. In order to simplify the CN update, other variants such as the MS, NMS, OMS and NOMS exist, and they represent a good compromise for the performance/complexity tradeoff.

The CN update of the BP-SPA may be given by:

$${x}_{i , e = ( v , c )} = 2 {tanh}^{- 1} ( {\prod }_{{e}^{′} - ( {v}^{′} , c ) , {v}^{′} \neq v} tanh ( \frac{1}{2} {x}_{i - 1 , {e}^{′}} ) )$$

While the VN update may take the following form:

$${x}_{i , e = ( v , c )} = {l}_{v} + {\prod }_{{e}^{′} - ( v , {c}^{′} ) , {c}^{′} \neq c} {x}_{i - 1 , {e}^{′}}$$

For the v^{th} VN, the marginalization step includes the following calculation:

$${o}_{v} = {l}_{v} + {\prod }_{{e}^{′} - ( v , {c}^{′} )} {x}_{i - 1 , {e}^{′}}$$

where lᵥ, is the LLR input associated to the v^{th} bit.

NBP is one of the most attractive solutions to decode all linear block codes with low complexity and low latency. It is also a promising approach to make the decoding block data-driven and to further enhance the performance.

NBP may include considering the unrolled version of the Tanner Graph across all the decoding iterations, and to learn the edges connecting variable nodes to check nodes. The motivation behind using the NBP for decoding linear block codes is that NBP allows to compensate the negative impact of short cycles, known to be one of the main causes of performance degradation in BP. If the edges are learned optimally, the messages passed from edges arising from short cycles are attenuated, which pushes the decoder to minimize the error propagation effect caused by the existence of short cycles.

Similarly to plain BP, NBP can be applied to different variants of the BP, which enables the possibility to consider these simplified check-node updates for sake of lower complexity and latency, while improving performance compared to the plain BP-SPA. Also, the NBP can be further employed to decode PR-LDPC codes for improving their performance.

NBP can be presented by a DNN, with an input layer fed by the LLR initializations, which means that the number of processing units (neurons) in the input layer is equal to the codelength n. The DNN structure is made up of several hidden layers, where each unfold of hidden layers represents a VN update layer followed by a CN update layer. Depending on the architecture of the NBP, these layers can be followed by a marginalization layer, in which case the DNN may not be processed entirely during the inference phase, since the marginalization layer outputs LLR estimates that enable the calculation of the syndrome weight, used as stopping criteria. The output layer of the NBP model includes n LLR estimates activated using a Sigmoid function. In this case, the NBP has a RNN architecture that consists of Lₘₐₓ unfolds. In the other case, there is just one marginalization layer, as output layer, and in this case, the number of hidden layers is equal to 2Lₘₐₓ, and the architecture is Feed-Forward (FF). In general, the DNN graph architecture of the NBP is related to the Tanner Graph, and the layers ae not fully connected. The neurons of the NBP are the nodes (CNs and VNs) of the tanner Graph, and the edges are the connections between these nodes (non-zero elements of the PCM associated to the code).

The edges of the NBP can be trained across all the iterations and have different weights, in this case the NBP architecture is FF. When the weights are temporally tied, i.e., the edges share the same weights during all the iterations, then the NBP architecture is RNN and includes a repetition of the same unfold (VN layer->CN layer->marginalization layer). In another option, the weights can be tied spatially and temporally, which means that all the edges share the same weight across all decoding iterations. This simplified architecture is called Simple Scaling (SS), and helps to significantly reduce storage requirements, training and inference decoding complexity.

The calculations involved in each hidden layer type of the NBP are represented below. Also, the different CN updates associated to different BP variants are represented. Note that these updates correspond to the FF architecture of different variants, FNSPA, FNMS and FNOMS.

$$VN layer$$

$${x}_{i , e = ( v , c )} = tanh ( \frac{1}{2} ( {w}_{i , v} {l}_{v} + {\prod }_{{e}^{′} - ( v , {c}^{′} ) , {c}^{′} \neq c} {w}_{i , e , {e}^{′}} {x}_{i - 1 , {e}^{′}} ) )$$

$$CN layer$$

$$FNSPA$$

$${x}_{i , e = ( v , c )} = 2 {tanh}^{- 1} ( {\prod }_{{e}^{′} - ( v , {c}^{′} ) , {c}^{′} \neq c} {x}_{i - 1 , {e}^{′}} )$$

$$FNMS$$

$${x}_{i , e = ( v , c )} = {w}_{i , e = ( v , c )} \cdot ( {min}_{{e}^{′}} \vert {x}_{i - 1 , {e}^{′}} \vert {\prod }_{{e}^{′}} sign ( {x}_{i - 1 , {e}^{′}} ) ) , {e}^{′} = ( {v}^{′} , c ) , {v}^{′} \neq v$$

$$FNOMS$$

$${x}_{i , e = ( v , c )} = max ( {min}_{{e}^{′}} \vert {x}_{i - 1 , {e}^{′}} \vert - {β}_{i . e = ( v , c )} , 0 ) {\prod }_{{e}^{′}} sign ( {x}_{i - 1 , {e}^{′}} ) , {e}^{′} = ( {v}^{′} , c ) , {v}^{′} \neq v$$

$$Marginalization layer$$

$${o}_{v} = σ ( {w}_{2 L + 1 , v} {l}_{v} + {\sum }_{{e}^{′} = ( v , {c}^{′} )} {w}_{2 L + 1 , v . {e}^{′}} {x}_{2 L , {e}^{′}} )$$

$$where σ ( x ) = \frac{1}{1 + {e}^{- x}}$$

is the Sigmoid activation function.

The intrinsic weights w_{i,v} and marginalization weights w_{2L+1,v} have shown to have negligible impact on the performance and thus can be discarded; in contrast to the weights used in the VN layer and in the CN layer for the simplified variants, where in the FNMS, the trainable weight is the normalization factor, and in the FNOMS is the offset parameter. Note that when the trainable weights are equal to 1, then the algorithm is similar to the plain BP. Henceforth, if learned properly, the NBP decoders guarantee to perform better than the conventional decoders if the weights are initialized by 1 before training. In some examples, the weights may be or may correspond to previously trained weights. For instance, if the NBP has already been trained, then the weights may be initialized by their learned values.

For the RNN architectures of the NBP, namely the variants RNSPA, RNMS and RNOMS, the trainable weights may be simplified to w_{i,e=(v,c)}=w_{e=(v,c)}. For the SS schemes, the weights may share the same value for all the edges and decoding iterations, thus w_{i,e=(v,c)}=w.

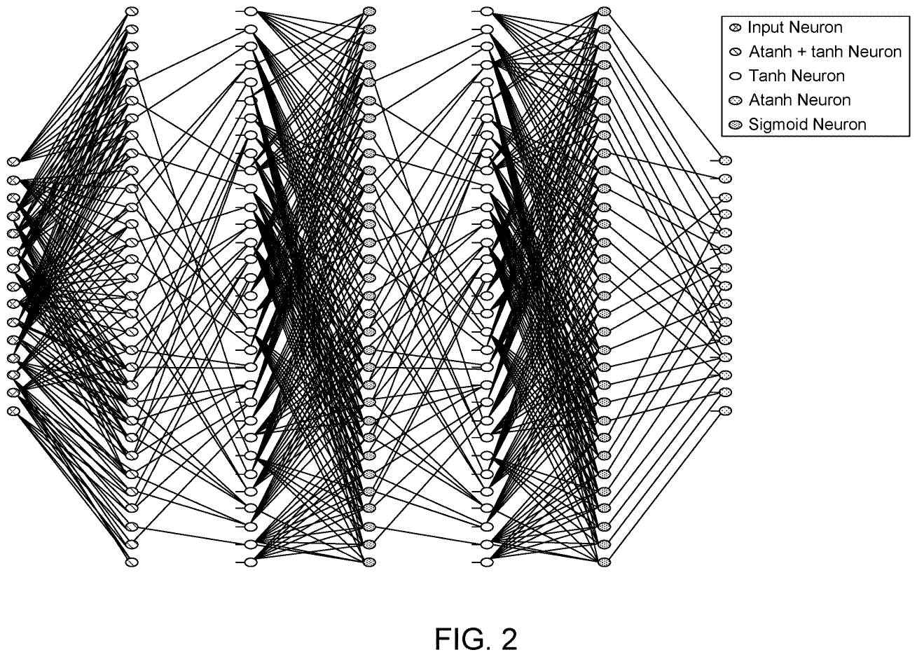

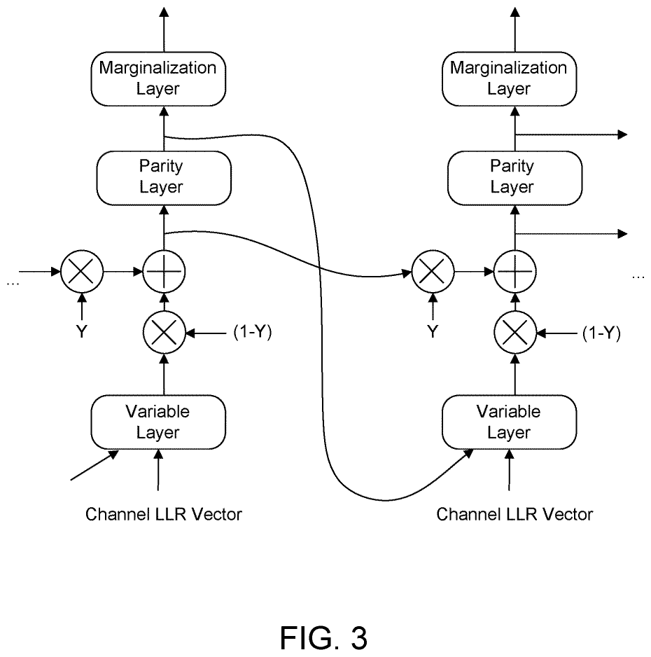

The architectures of FF and RNN based architectures of the NBP are illustrated in FIG. 2 and FIG. 3. FIG. 2 illustrates an example FNSPA decoding architecture with three decoding iterations for a code with n=15. As shown in FIG. 2, the unrolled Tanner Graph across decoding iterations (5 iterations in this case) is represented. The input node is the n=15 received symbols (channel outputs). The green nodes in the first hidden layer correspond to both CNs updates and VN updates, as the messages are initialized by zeros, thus only the CN update is calculated. The blue nodes correspond to VNs, while red nodes are CNs. The edges connecting the layers of nodes are the positions of non-zero entries in the PCM, based on which the reliability messages are calculated and passed. The output of the DNN is the result of the marginalization layer, which outputs n estimates of the LLRs corresponding to each coded bits.

In order to further improve the performance of the NBP by ML techniques, another trainable parameter can be added, a so-called relaxation or dumping parameter γ, and the resulting decoder is relaxed. The main benefit of the relaxation factor is helping to accelerate the convergence speed and improving performance by applying and exponentially weighted moving average to combine the message sent at iteration i−1 with the raw message computed in iteration i. This successive relaxation process yields to the following filtered message

$${x}_{i}^{′} = {γ x}_{i - 1}^{′} + ( 1 - γ ) {x}_{t} ,$$

where γ∈[0,1] is the relaxation factor. The decoder is less relaxed as γ→0, and more relaxed as γ→1. The decoder is not relaxed when γ=0. FIG. 3 illustrates an example of two unfolds of a relaxed RNN based NBP architecture.

Training a NBP decoder may incorporate different choices of objective functions. The most common one is the Binary Cross-Entropy (BCE) Multi-Loss function, which has the advantage to update the gradients after each decoding iteration, resulting in performance improvement and faster training convergence, in contrast to the conventional BCE. The Multi-Loss BCE function may take the following form:

$$L ( o , y ) = - \frac{1}{n} {\sum }_{i = 1}^{{L}_{max}} {\sum }_{v = 1}^{n} {y}_{v} log ( {o}_{v , i} ) + ( 1 - {y}_{v} ) log ( 1 - {o}_{v , i} )$$

where o_{v,i} is the output of the neural network for the v^{th} component of the transmitted codeword at the i^{th} decoding iteration, while yᵥ is the actual transmitted codeword symbol (label). Note that due to the symmetry property, the decoder can be trained using transmitted all-zero codewords, in which case yᵥ=0 for all 1≤v≤n.

Other loss functions may be considered as well in the NBP schemes, such as the Soft Bit Error Rate loss function, or the Soft Syndrome Weight loss function, which allows training to be unsupervised. Also, these functions can be combined into one general loss function.

Generally, artificial intelligence (AI) may be broadly defined as the behavior exhibited by machines. Such behavior may, for example, mimic cognitive functions to sense, reason, adapt and/or act.

Machine learning (ML) may refer to classes of algorithms that solve a problem based on learning through experience (‘data’), without explicitly being programmed (‘configuring set of rules’). Machine learning can be considered as a subset of AI. Different machine learning paradigms may be envisioned based on the nature of data or feedback available to the learning algorithm. For example, a supervised learning approach may involve learning a function that maps input to an output based on labeled training example, wherein each training example may be a pair consisting of input and the corresponding output. For example, an unsupervised learning approach may involve detecting patterns in the data with no pre-existing labels. For example, reinforcement learning approach may involve performing sequence of actions in an environment to maximize the cumulative reward. In some examples, it is possible to apply machine learning algorithms using a combination or interpolation of the above-mentioned approaches. For example, a semi-supervised learning approach may use a combination of a small amount of labeled data with a large amount of unlabeled data during training. In this regard semi-supervised learning falls between unsupervised learning (with no labeled training data) and supervised learning (with only labeled training data).

Deep learning (DL) refers to a class of machine learning algorithms that employ artificial neural networks (e.g., DNNs) which were loosely inspired from biological systems. Deep Neural Networks (DNNs) are a special class of machine learning models inspired by the human brain wherein the input is linearly transformed and passed through non-linear activation function multiple times. DNNs typically comprise multiple layers where each layer includes linear transformation and a given non-linear activation functions. The DNNs can be trained using the training data via back-propagation algorithm. Recently, DNNs have shown state-of-the-art performance in a variety of domains, e.g., speech, vision, natural language, etc. and for various machine learning settings including supervised, un-supervised, and semi-supervised. The term AIML based methods/processing may refer to realization of behaviors and/or conformance to requirements by learning based on data, without explicit configuration of sequence of steps of actions. Such methods may enable learning complex behaviors which might be difficult to specify and/or implement when using legacy methods.

As outlined above, the Belief Propagation decoder is a channel decoding algorithm that can be used in different communication systems for decoding LDPC codes, along with its different variants. The BP provides good performance while requiring a relatively low decoding latency.

A challenging problem relates to decoding other families of codes, such as Polar, RM and BCH codes with the BP algorithm while resulting in reasonable performance. Also, LDPC codes have shown limitations in short blocklength regimes, which is similar to other linear block codes due to the existence of short cycles in the dual structure of these codes, that dramatically impact the error rate performance. One such use-case that requires short blocklength communications includes, but is not limited to, 5G URLLC and mMTC use-cases, vehicular communications as well as other standards where codes such as Polar or BCH codes need to be decoded by low complexity and latency algorithms while preserving their performance robustness. Another problem is that the current channel coding schemes in 5G NR are static and not data-driven, and they do not consider the channel conditions or the communication scenario or use case. Also, user-centric channel coding is another feature that may lead to performance improvement in next releases.

Such a particular example is decoding Polar codes. Polar codes are capacity-achieving codes under CRC-aided Successive Cancellation List Decoding (CA-SCL), and they are already adopted in the 5G NR eMBB for control channels. However, CA-SCL decoding requires a very high latency and implementation complexity, which is not necessarily supported by some UE devices and use-cases. Also, BCH codes have demonstrated their capacity approaching performance in the short blocklength regime when decoded with the Ordered Statistics Decoder (OSD). Similarly, the OSD is a very complex decoder and although many proposed variants in the literature that aim to reduce its complexity, this algorithm is potentially not recommended for many use cases that require high speed communications.

One promising solution for optimizing the performance/latency/complexity trade-off for short blocklength communications and for different codes is the use of neural BP decoders, that have the feature to enable data driven decoding based on various channel types and conditions, while learning the parameters of the decoder which allows to compensate the negative impact of short cycles, while preserving the low latency characteristic of these decoders at the cost of performance improvement. NBP decoding has shown attractive performance for various families of codes and has the feature to be adaptive to different channel conditions, along with different degrees of freedom for further optimization. NBP decoding may eventually be the most adequate decoding scheme for the PR-LDPC BGs already adopted in the 5G NR eMBB, and will probably be considered for other 5G use cases and 6G communications as most likely candidate channel coding schemes.

Representative embodiments discussed herein may address several problems. For example, some problems addressed by some example embodiments may include at least the following: how to overcome the negative impact of short cycles on the performance of current channel coding schemes (5G NR) and in general for different codes characterized by a PCM and decoded by message-passing algorithms; how to further improve the performance (BLER) of the 5G NR channel codes, especially for short blocklength transmissions where performance is limited; how to reduce the decoding latency; how to enable a dynamic data-driven cannel coding mechanism instead of a static approach; how to enable user-centric channel decoding; and how to enable message exchange between UE and gNB for supporting online NBP training and performance monitoring.

In example embodiments discussed herein, methods for addressing the use of different variants and architectures of NBP decoders are described for decoding any arbitrary class of codes. For example, certain embodiments include enablers and/or procedures for UE pre-configuration, online NBP joint and distributed training, SNR adaptive training of a Parameter Adapter Network(s) by the UE, methods for the selection of the NBP variant and/or architecture depending on various user-centric metrics, and/or methods for evaluating and updating the weights associated to trained decoders.

It should be noted that in certain embodiments described herein a NBP variant may be interchangeably referred to as a NBP architecture. Additionally, in some embodiments, a NBP variant or a NBP architecture may alternately refer to or include a NBP model, for example. Therefore, as described herein, a NBP variant or architecture can be alternatively referred to as a NBP model.

Certain embodiments may include methods, apparatuses, systems, etc., which may be directed to individual and/or joint training and evaluation of NBP decoder(s).

In various embodiments, a method for, and/or for use in connection with, training and/or evaluation of NBP decoder(s) may be implemented in a WTRU. According to some embodiments, the WTRU may perform the training individually, jointly/disjointly with the gNB, and/or distributively/collaboratively with other WTRUs. In an embodiment, the method may include any of: receiving a Training Indicator (TI) from the gNB; transmitting a Training Configuration Request (TCR), to the gNB, along with FEC code parameters; receiving a Training Configuration (TC) from the gNB; transmitting a Training Ready Indicator (TRI) to the gNB; receiving the dataset subsequently from the gNB; transmitting a Training Progress Indicator (TPI) to the gNB, e.g., after every training epoch, after each M epoch, and/or after training is complete; and transmitting a Training Complete Indicator (TCI), e.g., after completing all the training epochs and/or if the loss function of the model starts to diverge above a pre-defined threshold T. In various embodiments, if the training is joint and/or disjoint, the messaging steps above may be executed bidirectionally (e.g., to/from the WTRU and gNB).

In various embodiments, a method for, and/or for use in connection with, updating the NBP model and the performance table may be implemented in a WTRU. According to some example embodiments, the method may include receiving a BLER Reference Signal (BRS) from the gNB, which may contain pairs of SNR/BLER values and/or the NBP model index. The method may also include comparing the newly updated BLER performance with the stored BLER table, deciding if the weights of the NBP model should be updated or not, and/or transmitting an Update Model Indicator (UMI) to the gNB.

Certain embodiments may include methods, apparatuses, systems, etc., which may be directed to distributive training and evaluation of NBP decoders. For example, for distributive training, one or more (e.g., several or multiple) WTRUs may participate, and the gNB may initiate the training by transmitting and/or broadcasting a Training Indicator (TI), e.g., periodically, aperiodically, and/or triggered by the WTRUs. In an embodiment, the method may include receiving the TI by each of the WTRU(s) participating in the distributive training/evaluation. The method may include the WTRU(s) transmitting a TCR to the gNB, receiving a Training Configuration Signal (TCS) from the gNB, and/or transmitting the calculated gradients and the training epoch index to the gNB. In an embodiment, the method may also include transmitting a Training Complete Indicator (TCI) to the gNB after completing the training process.

With respect to the evaluation of the NBP, the method may include the WTRU(s) transmitting and/or receiving an Evaluation Request Indicator (EQI) containing or indicating, for example, the NBP model index and/or the Monte-Carlo parameters. Alternatively or additionally, if the evaluation is distributive, the EQI may be broadcasted to one or more (e.g., several or multiple) WTRUs. In an embodiment, the method may include the WTRU(s) receiving an Evaluation Ready Indicator (ERI) from the gNB and/or transmitting an ERI to the gNB in case of distributive evaluation. According to some embodiments, the method may include the WTRU(s) transmitting a set of codewords along with their index, and/or receives an Evaluation Complete Indicator (ECI) from the gNB when the stopping criteria are met.

Certain embodiments may include methods, apparatuses, systems, etc. directed to SNR adaptive training. In various embodiments, a method for, and/or for use in connection with, SNR adaptive training may be implemented in a WTRU. According to some embodiments, the method may include the WTRU training the PAN model jointly with the NBP model or separately from (e.g., serially) the NBP model. In the case of joint training with the NBP model, the method may include the WTRU transmitting a Parameter Adapter Training Request (PATR) with the TCR altogether to the gNB. In the case of training the PAN model separately from (e.g., serially) the NBP model, the method may include transmitting a PATR to the gNB and receiving a PAN Configuration Signal (PCS) from the gNB. The PCS may contain or indicate the PAN architecture and parameters (e.g., may be implicit or explicit) and/or a CSI-RS for estimating the channel.

In addition, certain embodiments may include methods, apparatuses, systems, etc., which may be directed to inference of NBP models.

Some example embodiments may include methods for configuring NBP models. In various embodiments, a UE may be configured to support different NBP architectures and variants, such as, but not limited to, FNSPA, RNSPA, FNNMS, RNNMS, NSPA-SS, and/or NNMS-SS. It is noted that this is not intended to be an exhaustive list of applicable architectures, as the applicable architectures can be broader than those listed above; however, these algorithms are provided as examples to consider different use-cases and address any requirements.

Given a code with a parity-check matrix, an objective may include to enable NBP decoding by training the edges of the associated Tanner Graph connecting VNs to CNs, i.e., non-zero elements of the PCM. The PCM may characterize a PR-LDPC code, such as Base-Graphs (BGs) used in the 5G NR eMBB in data channels, or a single PCM corresponding to a LDPC code, or to any arbitrary PCM associated to a Polar code, BCH code or RM code.

E may be or may represent the number of edges contained in a Tanner Graph, or equivalently the number of non-zero elements in a PCM. Assuming that the considered decoders are relaxed, the total number of trainable parameters to store by the UE may depend on the considered NBP architecture and/or variant. Since the parameters of RNN and SS architectures are temporally and spatially/temporally tied, these architectures may require less trainable parameters. The number of parameters may be independent from the variant (SPA or NMS). The parameters may include the weights that are connecting CNs to VNs in addition to one relaxation factor, considered tied over the iterations and edges. Thus, the number of parameters of the FF architectures (e.g., FNSPA and FNNMS) may be equal to (E×L)+1, while for the RNN architectures (e.g., RNSPA and RNNMS) the number of parameters may be equal to E+1. For the SS architectures (e.g., NSPA-SS and NNMS-SS), there may be only 2 parameters to train, since all the edge weights are tied. Table 1 below summarizes the total number of trainable parameters associated to different NBP decoding architectures.

TABLE 1

| NBP architecture | Number of trainable parameters |
|---|---|
| FNSPA, FNNMS | (E × L) + 1 |
| RNSPA, RNNMS | E + 1 |
| NSPA-SS, NNMS-SS | 2 |

According to some embodiments, the UE may be configured to store a table that maps or associates the parameters to different NBP variants and/or architectures. It is noted that each variant belonging to the same architecture, despite having the same number of weights, may have different values of the trained parameters. The UE may also be pre-configured by the maximum number of decoding iterations Lₘₐₓ, which indicates the number of hidden layers in the DNN architecture of the NBP.

For training a BG corresponding to PR-LDPC codes, such as those used in the 5G NR (BG1 and BG2), the UE may be configured to store the parameters associated to bundles of edges, i.e., the same bundle of edge shares the same trained weight, allowing to expand the same weight to all the edges belonging to the same bundle after the expansion operation defined by the expansion factor Z, which is determined during the rate-matching process. In another option, which may be similar to training a single PCM, the UE may be configured to store the parameters associated to one PCM resulting from expanding the BG. For example, this may be very useful for training individual edges in case the same codelength is often used in a particular use-case or application. This allows the training to be more specific to individual edges for further performance enhancement.

Other configurations that the UE may consider may include the ML hyperparameters of the NBP. For example, for each individual decoder, the UE may be pre-configured by an optimizer algorithm for updating the gradients adequately, these optimizers include SGD, ADAM and RMSPROP. Each optimizer may require its own parameters, for instance, ADAM requires the momentum and decay factor parameters. Also, the UE may be configured by the learning rate a associated to each optimizer and NBP decoder. Other hyperparameters may include the batch size, the number of training epochs, the stopping criteria as well as the objective function to incorporate. The different choices of the objective function are described below or elsewhere herein.

Some example embodiments may include methods for UE online training and/or evaluation of the NBP decoders. In an embodiment, the UE may be configured to perform online NBP training, for example, after being pre-configured. In this example, the UE may receive datasets from the gNB, which may be subsequently transmitted over different channel conditions.

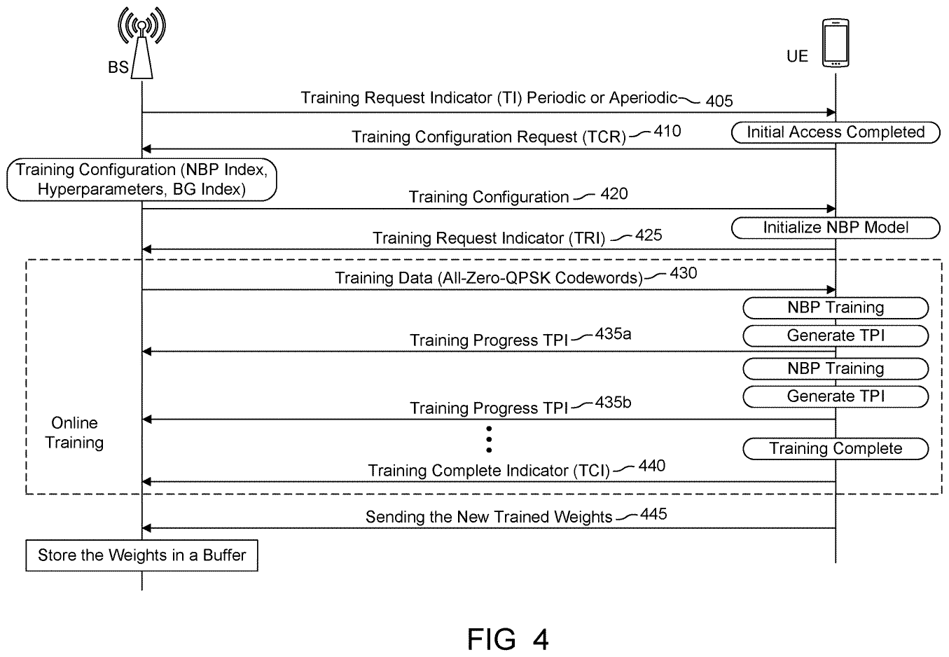

FIG. 4 illustrates an example signal flow diagram, according to one example embodiment. In various embodiments, as shown at 405, the gNB may be periodically transmitting a training request to the UE, using a Training Indicator (TI) through the PDCCH. The TI can be sent semi-periodically or periodically following a pre-defined timing configured by the network. Also, in another example, the TI may contain an indication about the number of OFDM symbol, slots and/or subframes after which the training is supposed to start. In case the UE is ready (e.g., prepared) for training, as shown at 410, the UE may send a training Configuration Request (TCR), e.g., to the gNB through the PUCCH, indicating or requesting to receive information about which NBP architecture to train, and/or about hyperparameter updates related to that specific NBP decoder variant or architecture. Otherwise, if the UE is unable to participate in training, or is unable to meet the indicated timing, the UE may respond, e.g., via PUCCH, with a negative confirmation indicator, or the UE may simply not respond thereby implicitly indicating to the gNB (e.g., the gNB knows) that the UE is not ready.

After sending a TCR, as shown at 420, the UE may receive training configuration information (e.g., a Training Configuration Signal (TCS)) through the PDSCH containing the index of the NBP variant to train, as well as any hyperparameter update. The hyperparameters are supposed to be known by the UE for each NBP model, by the help of configuration data containing a lookup table that maps or associates every NBP variant with its hyperparameters and weights. The UE may also receive, in the TCS, an indication of which BG to train (e.g., BG1 or BG2 in 5G NR eMBB), and/or other indications related to channel coding parameters, e.g., including the codelength N and code rate r. In an embodiment, after receiving all the parameters, as shown at 425, the UE may signal to the gNB that it is ready to start training, e.g., by transmitting a Training Ready Indicator (TRI) through the PUCCH. The TRI may be useful for making sure that the UE may refuse performing training in case its resources or battery life are limited, or in case the channel link with the gNB is very poor (for instance in case of underground or fast mobility). As shown at 430, the gNB may then proceed by progressively transmitting all—zero codewords. In one example embodiment, after each training epoch, the UE may signal or indicate the cost function value to the gNB, e.g., using a Training Progress Indicator (TPI) through the PUCCH as shown at 435a and 435b. In another example embodiment, the TPI may be fed back periodically after a set of M iterations (e.g., one or more iterations). In yet another example embodiment, the TPI can be sent after the training is completed.

To provide flexibility, different options may be provided with respect to the TPI. For instance, in one example, the TPI may contain the cost function value. In another example, the TPI may contain an indication of whether the cost function is increasing or decreasing, in which case only a 1-bit indicator might be used (e.g., 1 may indicate increasing, 0 may indicate decreasing). The TPI can be used to monitor the training progress and to decide if the model is converging or diverging. If the model starts to diverge, the gNB may decide to stop the training, e.g., if the cost function reaches a pre-defined threshold T (included in the pe-configuration). Other alternatives may be considered for the TPI, depending on the implementation.

In various embodiments, training may be executed jointly or disjointly (with partial alignment or without alignment) by the UE and gNB. In this case, the same signaling may be employed, however bidirectionally. In this example of joint or disjoint training, The TI for initiating training can be also sent by the UE to the gNB for requesting a joint training. Depending on if the UE or gNB initiates the procedure by a TI, the same procedure may follow with respect to the corresponding direction. The dataset in this scenario may be exchanged and the TPI may be subsequently exchanged as well. As mentioned above, the TPI may be transmitted periodically, semi-periodically or after processing a certain number of the training epochs (e.g., processing all the training epochs).

After processing the training iterations (e.g., this may refer to processing an appropriate number of iterations to deem the training complete or processing all the training iterations), the UE may indicate to the gNB that the training is complete, for example, by transmitting a Training Complete Indicator (TCI) via PUCCH, as shown at 440 in the example of FIG. 4. In one example, the TCI may be transmitted after completing all the training epochs. In another example, the UE may use a divergence threshold as a stopping criterion, wherein the UE may check if the cost function value is continuously diverging after a certain number, T, training epochs, where T is the divergence threshold (i.e., if the cost function is continuously increasing after T training epochs then the model should stop the training process). In this case, the UE may store the values of the weights obtained at the epoch before the ML model started to diverge.

Furthermore, in the case of joint training, the TCI may be transmitted by the UE or gNB, depending on which one has finished training the NBP model. When the TCI is transmitted and not received, the UE or gNB may continue to send the training dataset, until a TCI is received. After training the model by both the UE and gNB, the UE may send its weights to the gNB, which proceeds by averaging all the available weights.

Upon completion of the training or after the training is complete, as shown at 445, the UE may send the newly trained weights to the gNB, for example, through PUSCH for the performance monitoring (evaluation) phase. In one example, the transmitted weights may be compressed and encoded using the LDPC BG1 for enabling error detection and correction.

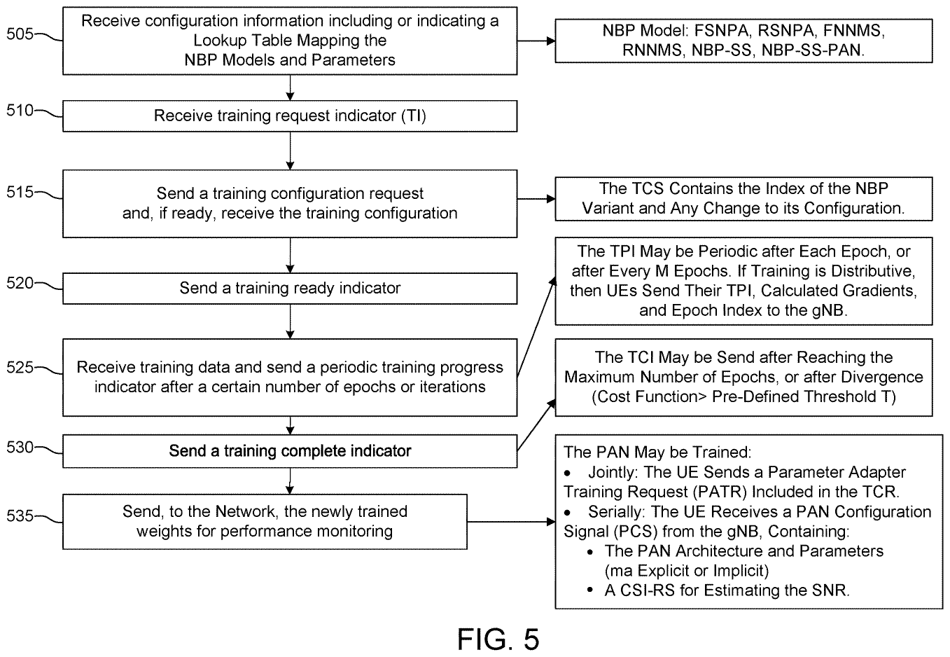

FIG. 5 illustrates an example flow diagram of a method for NBP training, according to an example embodiment. In various embodiments, the example method of FIG. 5 may be performed or implemented by a UE. However, in some embodiments, the method of FIG. 5 may be performed or implemented by other network elements or network nodes.

As illustrated in the example of FIG. 5, at 505, the UE may be configured with or may receive configuration information that includes (or indicates) a lookup table mapping (i.e., associating) the NBP models and parameters. For example, the parameters may include any one or more of weights, objective function, optimizer, hyperparameters, code parameters, etc. At 510, the UE may receive a request to perform training (e.g., a Training Indicator (TI) through the PDCCH, which may be a 1 bit indicator). As discussed above, the training request (e.g., TI) can be sent semi-periodically or periodically following a pre-defined timing configured by the network. In some examples, the TI may contain an indication about the number of OFDM symbol, slots and/or subframes after which the training is supposed to start. If or when the UE is ready (e.g., prepared) for training, as shown at 515, the UE may send a request for training configuration (e.g., Training Configuration Request (TCR)) to the gNB (e.g., through the PUCCH), which indicates the UE is ready to receive information about which NBP architecture or variant to train and/or about hyperparameter updates related to that specific NBP decoder variant or architecture. The UE may then receive the training configuration (e.g., in a training configuration signal (TCS) via PDSCH). At 520, the UE may send a training ready indicator (e.g., via PUCCH) indicating that it is ready to train the NBP variant/architecture and, at 525, the UE may receive training data and send one or more periodic training progress indicator(s) after one or more epochs or iterations of training (e.g., via PDSCH and PUCCH). At 530, after or upon completing training of the NBP variant or architecture, the UE may send an indication that training is complete, e.g., a training complete indicator (TCI) as discussed above (e.g, a 1 bit indication via PUCCH). At 535, the UE may send (e.g., via PUSCH) the newly trained weights associated with the trained NBP variant or architecture, e.g., to be used for evaluating the performance of the trained NBP variant or architecture.

For example, in a 5G NR eMBB use case, the channel coding scheme used for data channels relies on PR-LDPC codes, defined by 2 different BGs. The 3GPP currently adopts BG1 that targets moderate to high information blocklengths 500≤K≤8448, and intermediate to high code rates

$$\frac{1}{3} \leq r \leq \frac{8}{9} ,$$

while BG2 is targeting short to moderate information blocklengths 40≤K≤2560 and low to intermediate code rates

$$\frac{1}{5} \leq r \leq \frac{2}{3} .$$

Thousands of parity-check matrices can be generated from these 2 BGs, with different lengths and rate.

For PR-LDPC codes, for sake of simplicity and practicability, only bundles of edges are trained, and after expanding the BG to a PCM, edges emanating from the same bundle share the same trained weight. This is the default training configuration, and the UE may indicate to the gNB to activate this configuration by sending a Bundle of Edges Indicator (BEI) signal to the gNB, with one bit equal to 1 for the default configuration.

In some use cases or applications, the UE may use the same information blocklength subsequently, which implies the use of the same PCM associated to the expanded BG. In this scenario, the UE may request to train all the edges of the PCM, which may result in performance enhancement. In this case, the BEI is equal to 0 as a single PCM associated to a single LDPC code is trained.

After the NBP training is performed as outlined in detail above, the UE and gNB may evaluate the AI/ML decoding model before updating the trained weights. As a result, monitoring the performance of the NBP requires single transmissions (without HARQ process). Before the evaluation process starts, the UE and gNB may be dynamically configured by a performance table that maps some specific SNR values to the associated BLER performance. In other words, the UE and gNB may receive configuration information that includes or indicates a table that associates some specific SNR values to the associated BLER performance. Henceforth, updating the model after the evaluation process can be easily done if the BLER performance of the new model outperforms the previously stored model performance.

In various embodiments, the evaluating of the NBP model may use online Monte-Carlo simulations for collecting enough errors for each SNR value and obtaining accurate BLER performance that governs the model. The Monte-Carlo simulation of a large set of codewords over different SNR values may require computing resources and energy consumption, as the NBP decoder performs many decoding trials on the evaluation set. This may not be adequate for UE devices since it can imply a significant energy consumption which impacts the battery life. Thus, in some example embodiments, the evaluation process may be performed on the gNB side, where the UE transmits periodically a large set of codewords, for example, each codeword being sent individually. The process of evaluating a decoder may require channel links with various conditions in order to perform a diverse evaluation over different SNR ranges.

For enabling the evaluation process, the UE may send and/or receive an Evaluation Request Indicator (EQI), to/from the gNB, to indicate that the UE is ready for transmitting all-zero codewords for the sake of evaluating a specific NBP model. The EQI may be associated with the index of the NBP architecture and/or variant, as well as provide a padding pattern (ideally all-zero sequence) to help the gNB to perform an accurate estimate of the CQI. In addition, the EQI may include or indicate parameters for the simulation, including the minimum number of errors that should be collected per SNR value and/or the minimum number of blocks that should be collected per SNR. The UE may then receive an Evaluation Ready Indicator (ERI) from the gNB indicating that the gNB is ready to start receiving evaluation codewords. The evaluation codewords can be modulated using BPSK/QPSK for keeping the performance table small. However, in another example, if capabilities allow for it, higher order modulations and larger performance tables may be used. The UE may then start to transmit all-zero codewords that are decoded subsequently by the gNB, while storing the number of errors and index of the transmitted codeword. When the stopping criteria of the evaluation are met for a particular SNR, the UE may receive an Evaluation Complete Indicator (ECI) indicating that the evaluation is complete for a given SNR value.

It is noted that various embodiments discussed above and elsewhere herein provide several advantages and/or technological improvements. For instance, various embodiments may provide or facilitate data-centric channel coding that depends on the learned environment, which results in higher transmission reliability (i.e., better performance) and lower decoding latency (i.e., lower decoding iterations required). Further, according to various embodiments, online performance monitoring provides scalability of the NBP decoding AI/ML models, as well as adaptivity to new channels and transmission scenarios and environments.

Some example embodiments may include methods for distributive training and/or evaluation of NBP decoders. For example, various embodiments may include methods of distributed UE training, wherein more than one UE (e.g., multiple or many UEs) participate together in training a specific NBP decoding architecture/variant in a collaborative manner. Distributed training allows for a reduction in the training computational complexity on the UE side, by receiving less datasets, while providing diversity in SNR ranges by using different channel links through the same gNB. Additionally, the NBP model training speed can be significantly increased as it is processed in parallel by the UEs.

In this example of distributed training, the gNB may initiate a training request TI by transmitting it to several UEs. For example, the gNB may transmit periodic TI where the UEs may receive TI signaling from a gNB periodically, the gNB may transmit aperiodic TI where the UEs may receive TI in aperiodic fashion, and/or the TI may be triggered where the UEs may initiate training by transmitting a TI to a gNB.

In the periodic and aperiodic cases, the UE may inform the gNB that it is available for training by transmitting a TCR, followed for example by a response by the gNB containing the training configuration, e.g., using a training configuration signal (TCS). In the triggered TI, the UE may receive a TCR from the gNB and may then transmits a TCS containing the NBP and AI/ML parameters, for example.

In general, distributed training is asynchronous, where each UE trains its own received dataset independently. The UEs wishing to participate in NBP training may transmit the TCR, then receive a TCS, which means that the UEs share the same NBP model initial weights and parameters. In some examples, the TCR may contain or indicate information relating to the identity of the UE transmitting the TCR.

In collaborative training, each participating UE may send the calculated gradients to the gNB after each epoch. In this example, the gNB may be responsible for the gradients update and the cost function update rather than the UEs. Thus, the UE may be configured to send signaling indicating the current epoch and the calculated gradients, which allows the gNB to supervise the solution and cost function updates adequately.

Similar to UE and joint training, after the training is complete, each participating UE may inform the gNB that the training is complete, e.g., by sending a TCI signal.

The NBP evaluation at the gNB with a single UE may suffer from a lack of diversity, resulting in a longer delay for updating the model, as the gNB must wait for other EQI requests for diversifying the channel links, when the UE sounds a different channel condition. At least to overcome this (or similar) problem, the NBP evaluation may be collaborative, with the participation of different UEs having different channel links to the gNB. In this example, in contrast to what is discussed above, the EQI signal may be broadcasted to different UEs wishing to participate in the decoding evaluation. In this embodiment, the UEs may receive an EQI signal along with the NBP decoder index and the Monte-Carlo hyperparameters. It is noted that the new weights should not be shared as the UEs are just participating in the encoding process. Then, each UE may send an ERI indicator to initiate the evaluation process. The process may then proceed as discussed above similarly to the single UE evaluation process. Each participating UE may expect an ECI signal from the gNB when the evaluation is completed.

After the evaluation phase, for updating the model and performance table, the UE may receive the new BLER value as well as the NBP model index using a BLER Reference Signal (BRS) which helps the UE to decide whether to update the NBP model weights or keep the old values. As most of the evaluation is performed by the gNB, the gNB may report the results to the UE, and the UE may decide whether to update the trained weights. The update process may be based on the performance table available to the UE, for different NBP models. The performance table maps or associates, for each NBP model, BLER performance to SNR values. The UE may perform a comparison of the new BLER value received from the gNB using the BRS, and may then update the NBP ML model. After updating the NBP model and the weights, the UE may report, to the gNB, the update, e.g., by sending an Update Model Indicator (UMI) signal through PUCCH for confirming that the model is updated by the newly trained weights.

Some example embodiments may include methods for SNR adaptive training using a parameter adapter neural network. In some examples, training the NBP may cause the ML model to overfit or underfit. For instance, overfitting may be caused by excessively training the NBP in the high SNR regime, which enables the model to learn weights with low variance that are especially adapted to that regime. Consequently, the NBP model may be overfitting and, in the inference stage, it may not perform optimally over lower SNR values.

On the other hand, training the NBP in low SNR regime may prevent the model from efficiently learning the weights, as usually decoders are unable to make correct decisions in very low SNR values. Thus, in this case, the model is underfitting and may not perform well over other SNR regimes.

In general, training NBP models in the waterfall region is the approach for preventing overfitting and underfitting. However, for each code and code rate/codelength, the waterfall region may differ. The waterfall region is the SNR interval over which the BLER curve starts to fall. Finding the waterfall region for a specific code configuration is not an easy task and may not be accurate. Also, for each specific SNR value, the optimal NBP weights may be different, and it is generally unpractical to store weights for different SNR values as the set of SNRs is infinite.

Parameter Adapter Neural Networks (PANs) provide a good solution for enabling NBP models to be SNR independent, by allowing the NBP to be trained over different SNR values while retraining it, at the same time training a separate Shallow Neural Network (with one hidden layer), for adaptively scaling the trained weights of the NBP model with respect to the SNR value. This SNR adaptive PAN is a neural network with one hidden layer, that has one input unit, which is the SNR value, and few hidden neurons with a ReLU activation function, such that ReLU(x)=max (x, 0), and 1 output for each parameter, for the SS architecture which is the most convenient for this configuration. The NBP-SS architecture may have only 2 weights, in addition to one optional weight that can be used for scaling the LLR inputs. Thus, different PANs may be used by the UE for scaling different parameters. For the relaxation factor γ, the activation function in the output layer may be the Sigmoid function, since γ∈[0,1]. For the weight associated to all the edges, the activation function may also be the Sigmoid in addition to a scaling parameter for increasing the output scale, or the output layer may have no activation function.

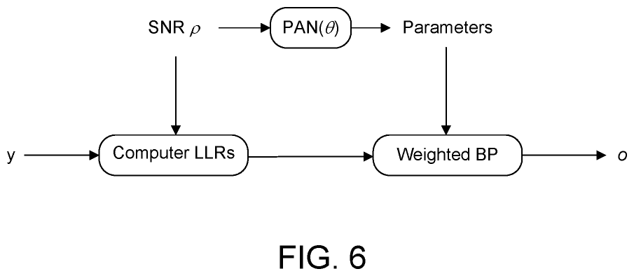

FIG. 6 illustrates an example a PAN architecture that may be used for SNR adaptive NBP decoding, according to various embodiments. In some embodiments, for training the PAN, the training procedure may be performed according to two different options. In one option, the PAN may be trained jointly with the NBP model. In another option, the PAN may be trained after (e.g., directly after) learning the NBP model weights.

According to various embodiments, the UE may initiate the PAN training by sending a Parameter Adapter Training Request (PATR), e.g., via PUCCH to the gNB, indicating that the UE is ready for collecting some dataset over a specific SNR. In one embodiment, the PATR may be included in the TCR, where the UE indicates that the PAN should be trained as well. For example, if the PATR is 0 (e.g., an indicator in the PATR is set to 0), then the PAN training is not required; otherwise, if the PATR is 1 (e.g., an indicator in the PATR is set to 1), then training the PAN is mandatory. The UE may then receive a PAN Confirmation Signal (PCS) from the gNB along with a CSI from which the UE is able to estimate the SNR value over which the PAN would be trained. The UE starts to subsequently receive QPSK modulated all-zero codewords for training the PAN. In one embodiment, the PATR may be sent jointly with the TCR for joint PAN/NBP training. In another embodiment, the PATR may be sent individually for indicating that the training is separate. The subsequent steps may be similar to the procedure for training the NBP AI/ML model, e.g., as discussed above with respect to FIGS. 4 and 5.

The methods of SNR adaptive training using a PAN, as described herein according to certain embodiments, provides several technological advantages and/or improvements. For example, the separate training of a PAN allows for use of a very low complexity and/or latency NBP model (NBP-SS-PAN), while performance is better than the conventional decoders. Additionally, the decoder has the ability to adapt its parameters to different channel conditions that are not necessarily observed during dataset collection.

Some example embodiments may include methods for inference and user-centric selection of a NBP model. The inference phase of the NBP decoders does not need the implementation of any DNN or AI/ML model. This is essentially due to the natural structure of BP decoders considered as message-passing, whereas the plain BP becomes a weighed BP and the weights are those trained during the training phase.

The trained weights are different from each NBP architecture and variant. Thus, in the inference stage, the UE may use different selection metrics for adequately choosing the NBP architecture to use for different use cases and scenarios.

The UE may store a lookup table that stores the trained weights associated to each NBP variant/architecture. Similarly, in one embodiment, the gNB may also store the same updated lookup table. Alternatively or additionally, in some embodiments, the weights may be sent from the UE to the gNB before the inference phase.

The selection metrics procedures used by the UE to select the NBP to use may be based on one or more of the following criteria: latency, computational complexity, reliability, channel conditions, and/or codelength/code rate.

The NBP architectures and variants provide different latencies. The decoding latency in NBP grows with the number of trained edges, the number of required decoding iterations and the computational complexity required for the check-node update. In an embodiment, the UE may use the convenient NBP model based on its requirements and available resources, including if decoding latency is tolerated in the considered use-case.

In an embodiment, the UE may choose the appropriate NBP model based on the computational complexity, which may be linked to the UE's battery life. The computational complexity is also related to the NBP architecture, where FF requires more complexity than RNN followed by the SS. Also, the variant plays a key role, since the simplified variants (NMS, NOMS) aim to reduce the complexity. The UE may be able to choose a NBP model dynamically based on the UE's preferences and resources.

In an embodiment, the UE may be able to select a NBP model based on its reliability, i.e., the BLER performance with respect to the SNR regime and channel model. The NBP models differ in terms of performance, and sometimes the performance is confused in some specific SNR intervals. The UE may consider whether or not, depending on the code structure and parameters, it is operating in the erroneous, waterfall or error floors region. In this case, after estimating the channel condition, the UE may decide which NBP model to employ in order to increase the transmission reliability.

The channel condition criterion may be related to reliability as well. Depending on the estimated SNR value, the UE may decide which NBP model to consider, based on the code structure, codelength and/or code rate. The BLER curve behavior depends on the code, codelength, code rate, and the SNR. In an embodiment, based on the observed SNR, the UE may choose the most optimal NBP model that minimizes the BLER performance.

In an embodiment, the UE may select the NBP model based on the codelength and code rate. The codelength and code rate influence the size of the PCM used for decoding, and thus the number of trained weights associated to different edges. Therefore, this criterion may also be related to the latency, computational complexity, and reliability metrics, as the dimension of the PCM impacts the complexity, latency, and performance. The UE may consider a combination of all these aforementioned criteria, in order to find an optimal compromise.

It is noted that, for the reliability and channel condition criteria, the UE's decision may be based on the performance table associated to each NBP model. The UE may also select the NBP model by combining a set of the aforementioned selection metrics.

Illustrating the difference between different NBP variants/architectures with respect to those metrics may not be easy and can also be data-driven, especially for the reliability. The priority for optimizing the reliability may be based on the stored performance table, which contains for each NBP decoder a set of SNR values and their BLER performance. Usually, the FF architectures perform better in the low SNR regime, and the SPA variant outperforms the other variants as well in low SNRs. However, this behavior changes in the high SNR regime, where the RNN architectures provide the same performance, and sometimes better if trained properly. This may be the same for the NMS variant compared to SPA, which can sometimes outperform it at the cost of lower latency and complexity. For the SS-PAN architecture, the complexity and latency are lower, at the cost of a poorer performance in low SNRs, and slight performance degradation in the high SNR regime. For the codelength metric, especially for LDPC codes, long lengths provide very satisfactory performance in contrast to short lengths. In fact, lower complexity/latency NBP variants/architectures may be a good choice for the long blocklength regime, and also especially for scenarios and use cases where latency plays a crucial role in meeting the requirements.

In various embodiments, for the inference stage in case the SS-PAN architecture is employed, the UE may receive the transmitted signal by the gNB, proceed by feeding the PAN by the estimated SNR of the channel link, and then adapt its NBP weights according to the output of the PAN. Then the UE may proceed by decoding the received sequence using the NBP decoder.

Accordingly, example embodiments discussed above advantageously allow the UE and network to adopt a user-centric channel coding approach, taking into account many metrics, and selecting the adequate NBP AI/ML model that can satisfy the requirements of the UE or network.

In view of the above, various embodiments may be directed to a method implemented in a Wireless Transmit/Receive Unit (WTRU). The method may include receiving, from a network element, training configuration information indicating (i) an index of a neural belief propagation (NBP) variant or architecture and/or (ii) an update to one or more received hyperparameters for the NBP variant or architecture. The method may include sending, to the network element, first information indicating that the WTRU is ready to train the NBP variant or architecture, and receiving, from the network element, a training dataset comprising all-zero codewords associated with a channel coding technique. The all-zero codewords may have a defined information block length and code rate. The method may then include starting training of the NBP variant or architecture using any of the received training dataset and the hyperparameters. After one or more training iterations, the method may include sending, to the network element, second information indicating a cost function value associated with the trained NBP variant or architecture and, on condition that the training is completed, sending, to the network element, third information indicating trained weights associated with the trained NBP variant or architecture.

An embodiment may be directed to a WTRU including circuitry (e.g., a processor, memory, and/or transceiver) configured to receive, from a network element, training configuration information indicating (i) an index of a neural belief propagation (NBP) variant or architecture and/or (ii) an update to one or more received hyperparameters for the NBP variant or architecture. The WTRU may be configured to send, to the network element, first information indicating that the WTRU is ready to train the NBP variant or architecture, and receive, from the network element, a training dataset comprising all-zero codewords associated with a channel coding technique. The all-zero codewords may have a defined information block length and code rate. The WTRU may be configured to begin training of the NBP variant or architecture using any of the received training dataset and the hyperparameters. After one or more training iterations, the WTRU may be configured to send, to the network element, second information indicating a cost function value associated with the trained NBP variant or architecture and, on condition that the training is completed, to send third information indicating trained weights associated with the trained NBP variant or architecture.

In various embodiments, the method may include, or the WTRU may be configured for, receiving configuration information indicating a lookup table associating NBP models and parameters. In other words, for example, the lookup table may associate NBP variants or architectures with hyperparameters.

In various embodiments, the NBP models may include a FNSPA, RNSPA, FNNMS, RNNMS, NBP-SS, and/or NBP-SS-PAN.

In various embodiments, the method may include, or the WTRU may be configured for, receiving a training indicator from the network element, where the training indicator comprises any of: an indication about the number of OFDM symbol, slots and subframes after which the training is supposed to start.

In various embodiments, the method may include, or the WTRU may be configured for, transmitting, to the network element, a request to receive the training configuration. In some embodiments, the second information may be sent after every training iteration, after a pre-defined set of iterations, and/or when the training is completed.

In various embodiments, the training is completed (e.g., considered to be completed) after completing all the training iterations or on a condition that a loss function of the NBP variant or architecture exceeds a pre-defined threshold.

In various embodiments, the method may include, or the WTRU may be configured for, receiving a BLER Reference Signal (BRS) from the network element, where the BRS may indicate pairs of SNR/BLER values and/or the index of the NBP. In an embodiment, the method may include (or the WTRU configured to) comparing the SNR/BLER values with those in a stored BLER table, determining whether weights of the NBP model should be updated based on the comparison and, on a condition that the weights are updated, transmitting an indication of the update to the model to the network element.

In various embodiments, the training may be performed collaboratively with, or among, at least one other WTRU (e.g., multiple WTRUs), and the third information may indicate calculated gradients and an index associated with a training iteration.

In various embodiments, the method may include, or the WTRU may be configured for, receiving or sending an evaluation request indicator indicating any of the NBP model index and Monte-Carlo parameters associated with the NBP model, receiving or sending an evaluation ready indicator (ERI), sending a set of codewords and their index, and receiving an evaluation complete indicator when a stopping criteria are met.

In various embodiments, the method may include, or the WTRU may be configured for, sending, to the network element, a request to train a parameter adapter network (PAN) and receiving, from the network element, a PAN configuration signal indicating any of: the PAN architecture and parameters, and/or a CSI-RS for estimating the channel.

In various embodiments, the request to train the PAN may be sent together with the request to receive the training configuration.

In various embodiments, the method may include, or the WTRU may be configured for, selecting the NBP variant or architecture using a selection criteria based on any one or more of: latency, complexity, reliability, channel condition, and code parameters.

Although features and elements are provided above in particular combinations, one of ordinary skill in the art will appreciate that each feature or element can be used alone or in any combination with the other features and elements. The present disclosure is not to be limited in terms of the particular embodiments described in this application, which are intended as illustrations of various aspects. Many modifications and variations may be made without departing from its spirit and scope, as will be apparent to those skilled in the art. No element, act, or instruction used in the description of the present application should be construed as critical or essential to the invention unless explicitly provided as such. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods or systems.

In some example embodiments described herein, (e.g., configuration) information may be described as received by a WTRU from the network, for example, through system information or via any kind of protocol message. Although not explicitly mentioned throughout embodiments described herein, the same (e.g., configuration) information may be pre-configured in the WTRU (e.g., via any kind of pre-configuration methods such as e.g., via factory settings), such that this (e.g., configuration) information may be used by the WTRU without being received from the network.

Any characteristic, variant or embodiment described for a method is compatible with an apparatus device comprising means for processing the disclosed method, such as with a device comprising a processor configured to process the disclosed method, a computer program product comprising program code instructions and a non-transitory computer-readable storage medium storing program instructions.

The foregoing embodiments are discussed, for simplicity, with regard to the terminology and structure of infrared capable devices, i.e., infrared emitters and receivers. However, the embodiments discussed are not limited to these systems but may be applied to other systems that use other forms of electromagnetic waves or non-electromagnetic waves such as acoustic waves.

It is also to be understood that the terminology used herein is for the purpose of describing particular embodiments only, and is not intended to be limiting. As used herein, the term “video” or the term “imagery” may mean any of a snapshot, single image and/or multiple images displayed over a time basis. As another example, when referred to herein, the terms “user equipment” and its abbreviation “UE”, the term “remote” and/or the terms “head mounted display” or its abbreviation “HMD” may mean or include (i) a wireless transmit and/or receive unit (WTRU); (ii) any of a number of embodiments of a WTRU; (iii) a wireless-capable and/or wired-capable (e.g., tetherable) device configured with, inter alia, some or all structures and functionality of a WTRU; (iii) a wireless-capable and/or wired-capable device configured with less than all structures and functionality of a WTRU; or (iv) the like. Details of an example WTRU, which may be representative of any WTRU recited herein, are provided herein with respect to FIGS. 1A-1D. As another example, various disclosed embodiments herein supra and infra are described as utilizing a head mounted display. Those skilled in the art will recognize that a device other than the head mounted display may be utilized and some or all of the disclosure and various disclosed embodiments can be modified accordingly without undue experimentation. Examples of such other device may include a drone or other device configured to stream information for providing the adapted reality experience.

In addition, the methods provided herein may be implemented in a computer program, software, or firmware incorporated in a computer-readable medium for execution by a computer or processor. Examples of computer-readable media include electronic signals (transmitted over wired or wireless connections) and computer-readable storage media. Examples of computer-readable storage media include, but are not limited to, a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs). A processor in association with software may be used to implement a radio frequency transceiver for use in a WTRU, UE, terminal, base station, RNC, or any host computer.

Variations of the method, apparatus and system provided above are possible without departing from the scope of the invention. In view of the wide variety of embodiments that can be applied, it should be understood that the illustrated embodiments are examples only, and should not be taken as limiting the scope of the following claims. For instance, the embodiments provided herein include handheld devices, which may include or be utilized with any appropriate voltage source, such as a battery and the like, providing any appropriate voltage.

Moreover, in the embodiments provided above, processing platforms, computing systems, controllers, and other devices that include processors are noted. These devices may include at least one Central Processing Unit (“CPU”) and memory. In accordance with the practices of persons skilled in the art of computer programming, reference to acts and symbolic representations of operations or instructions may be performed by the various CPUs and memories. Such acts and operations or instructions may be referred to as being “executed,” “computer executed” or “CPU executed.”

One of ordinary skill in the art will appreciate that the acts and symbolically represented operations or instructions include the manipulation of electrical signals by the CPU. An electrical system represents data bits that can cause a resulting transformation or reduction of the electrical signals and the maintenance of data bits at memory locations in a memory system to thereby reconfigure or otherwise alter the CPU's operation, as well as other processing of signals. The memory locations where data bits are maintained are physical locations that have particular electrical, magnetic, optical, or organic properties corresponding to or representative of the data bits. It should be understood that the embodiments are not limited to the above-mentioned platforms or CPUs and that other platforms and CPUs may support the provided methods.

The data bits may also be maintained on a computer readable medium including magnetic disks, optical disks, and any other volatile (e.g., Random Access Memory (RAM)) or non-volatile (e.g., Read-Only Memory (ROM)) mass storage system readable by the CPU. The computer readable medium may include cooperating or interconnected computer readable medium, which exist exclusively on the processing system or are distributed among multiple interconnected processing systems that may be local or remote to the processing system. It should be understood that the embodiments are not limited to the above-mentioned memories and that other platforms and memories may support the provided methods.

In an illustrative embodiment, any of the operations, processes, etc. described herein may be implemented as computer-readable instructions stored on a computer-readable medium. The computer-readable instructions may be executed by a processor of a mobile unit, a network element, and/or any other computing device.

There is little distinction left between hardware and software implementations of aspects of systems. The use of hardware or software is generally (but not always, in that in certain contexts the choice between hardware and software may become significant) a design choice representing cost versus efficiency tradeoffs. There may be various vehicles by which processes and/or systems and/or other technologies described herein may be effected (e.g., hardware, software, and/or firmware), and the preferred vehicle may vary with the context in which the processes and/or systems and/or other technologies are deployed. For example, if an implementer determines that speed and accuracy are paramount, the implementer may opt for a mainly hardware and/or firmware vehicle. If flexibility is paramount, the implementer may opt for a mainly software implementation. Alternatively, the implementer may opt for some combination of hardware, software, and/or firmware.

The foregoing detailed description has set forth various embodiments of the devices and/or processes via the use of block diagrams, flowcharts, and/or examples. Insofar as such block diagrams, flowcharts, and/or examples include one or more functions and/or operations, it will be understood by those within the art that each function and/or operation within such block diagrams, flowcharts, or examples may be implemented, individually and/or collectively, by a wide range of hardware, software, firmware, or virtually any combination thereof. In an embodiment, several portions of the subject matter described herein may be implemented via Application Specific Integrated Circuits (ASICs), Field Programmable Gate Arrays (FPGAs), digital signal processors (DSPs), and/or other integrated formats. However, those skilled in the art will recognize that some aspects of the embodiments disclosed herein, in whole or in part, may be equivalently implemented in integrated circuits, as one or more computer programs running on one or more computers (e.g., as one or more programs running on one or more computer systems), as one or more programs running on one or more processors (e.g., as one or more programs running on one or more microprocessors), as firmware, or as virtually any combination thereof, and that designing the circuitry and/or writing the code for the software and or firmware would be well within the skill of one of skill in the art in light of this disclosure. In addition, those skilled in the art will appreciate that the mechanisms of the subject matter described herein may be distributed as a program product in a variety of forms, and that an illustrative embodiment of the subject matter described herein applies regardless of the particular type of signal bearing medium used to actually carry out the distribution. Examples of a signal bearing medium include, but are not limited to, the following: a recordable type medium such as a floppy disk, a hard disk drive, a CD, a DVD, a digital tape, a computer memory, etc., and a transmission type medium such as a digital and/or an analog communication medium (e.g., a fiber optic cable, a waveguide, a wired communications link, a wireless communication link, etc.).

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein may be integrated into a data processing system via a reasonable amount of experimentation. Those having skill in the art will recognize that a typical data processing system may generally include one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity, control motors for moving and/or adjusting components and/or quantities). A typical data processing system may be implemented utilizing any suitable commercially available components, such as those typically found in data computing/communication and/or network computing/communication systems.

The herein described subject matter sometimes illustrates different components included within, or connected with, different other components. It is to be understood that such depicted architectures are merely examples, and that in fact many other architectures may be implemented which achieve the same functionality. In a conceptual sense, any arrangement of components to achieve the same functionality is effectively “associated” such that the desired functionality may be achieved. Hence, any two components herein combined to achieve a particular functionality may be seen as “associated with” each other such that the desired functionality is achieved, irrespective of architectures or intermedial components. Likewise, any two components so associated may also be viewed as being “operably connected”, or “operably coupled”, to each other to achieve the desired functionality, and any two components capable of being so associated may also be viewed as being “operably couplable” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, where only one item is intended, the term “single” or similar language may be used. As an aid to understanding, the following appended claims and/or the descriptions herein may include usage of the introductory phrases “at least one” and “one or more” to introduce claim recitations. However, the use of such phrases should not be construed to imply that the introduction of a claim recitation by the indefinite articles “a” or “an” limits any particular claim including such introduced claim recitation to embodiments including only one such recitation, even when the same claim includes the introductory phrases “one or more” or “at least one” and indefinite articles such as “a” or “an” (e.g., “a” and/or “an” should be interpreted to mean “at least one” or “one or more”). The same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, the terms “any of” followed by a listing of a plurality of items and/or a plurality of categories of items, as used herein, are intended to include “any of,” “any combination of,” “any multiple of,” and/or “any combination of multiples of” the items and/or the categories of items, individually or in conjunction with other items and/or other categories of items. Moreover, as used herein, the term “set” is intended to include any number of items, including zero. Additionally, as used herein, the term “number” is intended to include any number, including zero. And the term “multiple”, as used herein, is intended to be synonymous with “a plurality”.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein may be readily broken down into a lower third, middle third and upper third, etc. As will also be understood by one skilled in the art all language such as “up to,” “at least,” “greater than,” “less than,” and the like includes the number recited and refers to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

Moreover, the claims should not be read as limited to the provided order or elements unless stated to that effect. In addition, use of the terms “means for” in any claim is intended to invoke 35 U.S.C. § 112, ¶6 or means-plus-function claim format, and any claim without the terms “means for” is not so intended.

Although various embodiments have been described in terms of communication systems, it is contemplated that the systems may be implemented in software on microprocessors/general purpose computers (not shown). In certain embodiments, one or more of the functions of the various components may be implemented in software that controls a general-purpose computer.

In addition, although some example embodiments are illustrated and described herein, the invention is not intended to just be limited to the details shown. Rather, various modifications and variations may be made in the details within the scope and range of equivalents of the claims and without departing from the spirit or scope invention.

### REFERENCES

The following references may have been referred to hereinabove, each of which is incorporated herein by reference in its entirety:
3GPP TS 38.212, “Multiplexing and channel coding”, v16.0.0;
Nachmani, Eliya et al. “Learning to decode linear codes using deep learning.” 2016 54th Annual Allerton Conference on Communication, Control, and Computing (Allerton) (2016): 341-346;
E. Nachmani, E. Marciano, L. Lugosch, W. J. Gross, D. Burshtein and Y. Be'ery, “Deep Learning Methods for Improved Decoding of Linear Codes,” in IEEE Journal of Selected Topics in Signal Processing, vol. 12, no. 1, pp. 119-131, February 2018, doi: 10.1109/JSTSP.2017.2788405;
L. Lugosch and W. J. Gross, “Learning from the syndrome,” in Asilomar Conference on Signals, Systems, and Computers, special session on “Machine Learning for Wireless Systems”, October 2018;
L. Lugosch and W. J. Gross, “Neural offset min-sum decoding,” IEEE International Symposium on Information Theory (ISIT), Aachen, 2017, pp. 1361-1365; and
Dai, J., Tan, K., Si, Z., Niu, K., Chen, M., Vincent Poor, H., & Cui, S. (2021). Learning to Decode Protograph LDPC Codes. IEEE Journal on Selected Areas in Communications, 39(7), 1983-1999. [9427170].

### Partial Glossary of Abbreviations and Acronyms

ACK Acknowledgement
ADAM Adaptive Moment
AE Autoencoder
AI Artificial Intelligence
AIML Artificial Intelligence/Machine Learning
BCH Bose-Chaudhuri-Hocquenghem
BG Base-Graph
BLER Block Error Rate
BP-MS Belief-Propagation Min-Sum
BP-SPA Belief-Propagation Sum-Product Algorithm
CA-SCL CRC-Aided Successive Cancellation List
CN Check Node
CRC Cyclic Redundancy Check
CSI Channel State Information
D2D Device to Device transmissions (e.g., LTE Sidelink)
DL Downlink
eMBB Enhanced Mobile Broadband
FEC Forward Error Correction
FF Feed-Forward
FNSPA Feed-Forward Neural Sum-Product Algorithm
gNB NR NodeB
HARQ Hybrid Automatic Repeat Request
LDPC Low-Density Parity-Check
LLR Log-Likelihood Ratio
MCS Modulation and Coding Scheme
MIMO Multiple Input Multiple Output
ML Machine Learning
MTC Machine-Type Communications
NACK Negative ACK
NBP Neural Belief-Propagation
NNMS Neural Normalized Min-Sum
NOMS Neural Offset Min-Sum
NR New Radio
OSD Ordered Statistics Decoder
PCM Parity-Check Matrix
PHY Physical Layer
PRB Physical Resource Block
PR-LDPC Protograph Low-Density Parity-Check
ReLU Rectified Linear Unit
RMSPROP Root Mean Square Propagation
RM Reed-Muller
RNN Recurrent Neural Networks
RNSPA Recurrent Neural Sum-Product Algorithm
RS Reference Signal
SGD Stochastic Gradient-Descent
TRx Transceiver
UL Uplink
URLLC Ultra-Reliable and Low Latency Communications
VN Variable Node.

1. A method, implemented in a Wireless Transmit/Receive Unit (WTRU), the method comprising:
receiving, from a network element, training configuration information indicating any of: (i) an index of a neural belief propagation (NBP) variant or architecture and (ii) an update to one or more received hyperparameters for the NBP variant or architecture;
sending, to the network element, first information indicating that the WTRU is ready to train the NBP variant or architecture;
receiving a training dataset comprising all-zero codewords associated with a channel coding technique, the all-zero codewords having a defined information block length and code rate;
starting training of the NBP variant or architecture using any of the received training dataset and the hyperparameters;
after one or more training iterations, sending, to the network element, second information indicating a cost function value associated with the trained NBP variant or architecture; and
on condition that the training is completed, sending, to the network element, third information indicating trained weights associated with the trained NBP variant or architecture.

2. The method of claim 1, comprising:
receiving configuration information indicating a lookup table associating NBP variants or architectures with hyperparameters.

3. The method of claim 1, wherein the NBP variants or architectures comprise any of: Feed-Forward Neural Sum-Product Algorithm, Recurrent Neural Sum-Product Algorithm, Feed-Forward Neural Network Normalized Min-Sum, Recurrent Neural Network Normalized Min-Sum, NBP-synchronization signal (SS), NBP-SS-parameter adapter network (PAN).

4. The method of claim 1, comprising:
receiving a training indicator from the network element, wherein the training indicator comprises any of: an indication about the number of orthogonal frequency division multiplex (OFDM) symbol, slots or subframes after which the training is to start.

5. (canceled)

6. The method of claim 1, wherein the second information is sent after any of: every training iteration, a pre-defined set of iterations, or when the training is completed.

7. The method of claim 1, wherein the training is completed after completing all the training iterations or on a condition that a loss function of the NBP variant or architecture exceeds a pre-defined threshold.

8. The method of claim 1, comprising:
receiving a block error rate (BLER) Reference Signal (BRS) from the network element, the BRS indicating any of (i) pairs of signal-to-noise ratio (SNR)/BLER values and (ii) the index of the NBP;
comparing the SNR/BLER values with those in a stored BLER table;
based on the comparison, determining whether weights of the NBP variant or architecture should be updated; and
on a condition that the weights are updated, transmitting an indication of the updated weights to the network element.

9. The method of claim 1, wherein the training is performed collaboratively with, or among, at least one other WTRU, and wherein the third information indicates calculated gradients and an index associated with a training iteration.

10. The method of claim 1, comprising:
receiving or sending an evaluation request indicator indicating any of an index associated with the NBP variant or architecture and Monte-Carlo parameters associated with the NBP variant or architecture;
receiving or sending an evaluation ready indicator (ERI);
sending a set of codewords and their index; and
receiving an evaluation complete indicator when a stopping criteria are met.

11. The method of claim 1, comprising:
sending, to the network element, a request to train a parameter adapter network (PAN); and
receiving, from the network element, PAN configuration information indicating any of: the PAN architecture and parameters, and a channel state information reference signal (CSI-RS) for estimating a channel.

12. (canceled)

13. (canceled)

14. A Wireless Transmit/Receive Unit (WTRU), comprising:
circuitry including any of a transceiver, processor, and memory, the circuitry configured to
receive, from a network element, training configuration information indicating any of: (i) an index of a neural belief propagation (NBP) variant or architecture and (ii) an update to one or more received hyperparameters for the NBP variant or architecture;
send, to the network element, first information indicating that the WTRU is ready to train the NBP variant or architecture;
receive a training dataset comprising all-zero codewords associated with a channel coding technique, the all-zero codewords having a defined information block length and code rate;
start training of the NBP variant or architecture using any of the received training dataset and the hyperparameters;
after one or more training iterations, send, to the network element, second information indicating a cost function value associated with the trained NBP variant or architecture; and
on condition that the training is completed, send, to the network element, third information indicating trained weights associated with the trained NBP variant or architecture.

15. The WTRU of claim 14, the circuitry configured to:
receive configuration information indicating a lookup table associating NBP variants or architectures with hyperparameters.

16. The WTRU of claim 14, wherein the NBP variants or architectures comprise any of: Feed-Forward Neural Sum-Product Algorithm, Recurrent Neural Sum-Product Algorithm, Feed-Forward Neural Network Normalized Min-Sum, Recurrent Neural Network Normalized Min-Sum, NBP-synchronization signal (SS), NBP-SS-parameter adapter network (PAN).

17. The WTRU of claim 14, configured to:
receive a training indicator from the network element, wherein the training indicator comprises any of: an indication about the number of orthogonal frequency division multiplex (OFDM) symbol, slots and/or subframes after which the training is to start.

18. (canceled)

19. The WTRU of claim 14, wherein the second information is sent after any of: every training iteration, a pre-defined set of iterations, or when the training is completed.

20. The WTRU of claim 14, wherein the training is completed after completing all the training iterations or on a condition that a loss function of the NBP variant or architecture exceeds a pre-defined threshold.

21. The WTRU of claim 14, configured to:
receive a block error rate (BLER) Reference Signal (BRS) from the network element, the BRS indicating any of (i) pairs of signal-to-noise ratio (SNR)/BLER values and (ii) the index of the NBP;
compare the SNR/BLER values with those in a stored BLER table;
based on the comparison, determine whether weights of the NBP variant or architecture should be updated; and
on a condition that the weights are updated, transmit an indication of the updated weights to the network element.

22. The WTRU of claim 14, wherein the training is performed collaboratively with, or among, at least one other WTRU, and wherein the third information indicates calculated gradients and an index associated with a training iteration.

23. The WTRU of claim 14, configured to:
receive or send an evaluation request indicator indicating any of an index associated with the NBP variant or architecture and Monte-Carlo parameters associated with the NBP variant or architecture;
receive or send an evaluation ready indicator (ERI);
send a set of codewords and their index; and
receive an evaluation complete indicator when a stopping criteria are met.

24. The WTRU of claim 14, configured to:
send, to the network element, a request to train a parameter adapter network (PAN); and
receive, from the network element, PAN configuration information indicating any of: the PAN architecture and parameters, and a channel state information reference signal (CSI-RS) for estimating a channel.

25. (canceled)

26. (canceled)
